(19) United States
(12) Patent Application Publication
(10) Pub. No.: US 2024/0329626 A1
(43) Pub. Date: Oct. 3, 2024

(54) DIGITAL SIMULATION FOR SEMICONDUCTOR MANUFACTURING PROCESSES

(71) Applicant: Applied Materials, Inc., Santa Clara, CA (US)

(72) Inventors: Kay Siong NG, Singapore (SG); Yunpeng WU, Singapore (SG); Olivia Fatma KOENTJORO, Waterford Residence (SG); Roger Alan LINDLEY, Santa Clara, CA (US)

(21) Appl. No.: 18/191,710

(22) Filed: Mar. 28, 2023

(51) Int. Cl. G05B 19/418

(52) U.S. Cl. CPC G05B 19/41885; G05B 2219/45032

(57) ABSTRACT

The disclosure describes methods and systems for operating a manufacturing process with a concurrent real-time simulation of the manufacturing process via a digital twin model. Sensor data indicative of parameters of an ongoing manufacturing process are input into the digital twin model, and used to predict an output of the manufacturing process. The predicted output is compared to a target output. One or more trained machine learning models are used to determine a corrective action to be implemented by a controller of the manufacturing process to minimize any deviation from the target output.

### TECHNICAL FIELD

Embodiments of the present disclosure relate, in general, to manufacturing systems and more particularly to control of semiconductor processing systems using a model-based digital simulation.

### BACKGROUND

Semiconductor wafer processing complexity has been increasing as the device size has been shrinking. A typical process has multiple different steps, with some advanced processes, such as plasma etching, having twenty or even more steps. Each step has a multitude of knobs associated to optimize performance. Therefore, the space available to tune and optimize a given process is theoretically extremely large.

Process engineers use their experience and expertise to select a preliminary baseline process and fine-tune the process based on a limited number of wafers (or portions of wafers, referred to as coupons) dedicated for design of experiment (DoE). The goal of DoE is to tailor the process to achieve desired specification on a wafer. However, dedicating full wafers or portions of wafers for DoE data collection consumes valuable resources. Therefore, often the adopted process may be a viable one, but not necessarily the optimum solution.

In addition, the quality and consistency of substrates processed at the manufacturing system may drift away from the target quality and consistency associated with the process recipe over time. However, it may be difficult for an operator of the manufacturing system to identify a drift from the target quality and consistency, to determine the defective component that is causing the drift, and determine an appropriate action to address the drift in quality and consistency.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

[This section will be completed upon finalization of the claims.]

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 depicts an exemplary system architecture of the present disclosure.

FIG. 2 depicts a top schematic view of an example manufacturing system.

FIG. 3 depicts a schematic cross-sectional view of an exemplary processing chamber.

FIG. 4 depicts a schematic plan view of an exemplary faceplate of a showerhead.

FIG. 5 is a partial cross-sectional schematic side view detailing portions of a substrate support assembly having spatially tunable heaters.

FIGS. 6A-6D are top views of the substrate support assembly illustrating example layouts for the spatially tunable heaters.

FIG. 7 depicts a simplified timing diagram for a manufacturing process with concurrent real-time simulation.

FIG. 8 depicts an exemplary environment for a manufacturing process with concurrent real-time simulation.

FIG. 9 depicts another exemplary environment for a manufacturing process with concurrent real-time simulation.

FIG. 10 depicts another exemplary environment for a manufacturing process with concurrent real-time simulation.

FIG. 11 depicts an exemplary environment for real-time process control.

FIG. 12 depicts an exemplary method for real-time control of a manufacturing process with autonomous parameter adjustment.

FIG. 13 depicts an example machine of a computer system.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Described herein are technologies directed to real-time automated control of semiconductor manufacturing processes using a model-based digital simulation operating concurrently with the physical manufacturing process. Manufacturing equipment may be used to produce products (e.g., electronic devices). For example, manufacturing equipment may execute a recipe to produce electronic devices by suppling certain process gases at specified rates and times from specified nozzles of a pixelated showerhead, into a processing chamber to generate plasma for etching or deposition operations on a semiconductor wafer.

In some conventional systems, a process engineer manually adjusts process parameters if the process output deviates from the desired process output. However, this manual adjustment is subject to variation depending on the individual judgment of each person. Further, there is a time delay between when a person notices that a process drift is occurring, tries to determine what may be causing the drift, determines a process adjustment to be made, and inputs the desired adjustment into a controller of the manufacturing process.

The devices, systems, and methods disclosed herein provide real-time control of a manufacturing process with autonomous parameter adjustment while the manufacturing process is being executed. The real-time control of the process is achieved by running one or more computer simulations from one or more trained machine learning models of the process, concurrent with the operation of the actual process. The one or more trained machine learning models may be trained for processes performed by a particular manufacturing component. For example, the one or more trained machine learning models may be trained for pixelated-control of temperature for a substrate support such as an electrostatic chuck (ESC); pixelated-control of gas flow for a showerhead; pixelated-control of localized power for the generation of localized plasma, such as through the substrate support, and/or pixelated control of localized power for the generation of localized plasma through an upper electrode, such as an electrode i in a showerhead or process chamber lid. Further, a second set of machine learning model(s) compares the simulated results with target results and determines one or more adjustments that can be made to the process while it is being concurrently operated. The adjustments are then put through the computer simulations again to determine a predicted process result, and compare the predicted process result with the target results. If the adjustments are deemed to match with the target results, then a process controller is instructed to make those adjustments to the physical process in substantially real time.

Aspects of the present disclosure are directed to building a spatial model for predicting performance of semiconductor processing equipment (also referred to as “chamber”) using spatial digital DoE. The spatial model is also capable of digitally generating virtual recipes for any set of conditions within a process space. The term “virtual recipe” means a process recipe generated using a spatial digital model of a wafer, i.e., a virtual wafer, rather than a physical wafer or coupon. The term “virtual wafer” encompasses not only wafers, but other objects as well, such as masks to perform mask-based metrology. The spatial model uses machine-learning to leverage the synergy between metrology data and various knobs. The term “knob” is used to indicate variables that can be adjusted to control a process. Knobs are sometimes also referred to as process control variables, or simply process variables.

Real-time monitoring data of an ongoing process are input into a digital simulation associated with the manufacturing process. In some embodiments, the digital simulation associated with the manufacturing process is a digital replica, or digital “twin” of the manufacturing process, to simulate exact conditions of the manufacturing process. In other embodiments, the digital simulation may simulate only some conditions of the manufacturing process. Outputs indicative of predictive data may be obtained from the digital simulation. The outputs indicative of predictive data may be generated using a trained machine learning model, a heuristics model, or a rule based model. Based on the predictive data, the processing device may perform one or more corrective actions associated with the manufacturing equipment.

In some embodiments, the flow rate of certain process gases is adjustable in a pixelated showerhead of the processing chamber. The predictive data may include one or more gas flow rate adjustments for certain nozzles, or groups of nozzles, of the pixelated showerhead. The corrective action may include adjustment of the flow of a gas through one or more nozzles, or groups of nozzles, of the showerhead based on the predictive data.

In some embodiments, individually tunable heaters are present in a pixelated electrostatic chuck of the processing chamber. The predictive data may include one or more of an electrostatic chuck temperature, time of processing, type of gas, power, RF bias, pressure, or temperature in a processing chamber, among other parameters. The corrective action may include adjustment of an amount of power sent to one or more individually tunable heater, or groups of heaters, of the electrostatic chuck based on the predictive data.

In some embodiments, an amount or composition of plasma generated in the processing chamber is adjustable. The predictive data may include information regarding process gases, temperatures, flow rates, gas ratios, pressure, power profile information, and other parameters for the generation of plasma in the processing volume. The corrective action may include adjustment of an amount of power sent to one or more electrodes, or groups of electrodes, to adjust an amount of RF bias generated in the processing volume.

Aspects of the present disclosure result in technological advantages of significant reduction in time required to achieve optimal settings, and reduced energy consumption. By using signal processing, a digital simulation, and machine learning model(s) to obtain predictive data and cause performance of corrective actions based on the predictive data, iterations of trial and error can be reduced or avoided entirely. The present disclosure may result in predicting optimal parameter settings associated with an etching or deposition process to avoid inconsistent and abnormal products, unscheduled user time, and damage to manufacturing equipment. While exemplary embodiments discussed herein refer to showerhead related manufacturing processes, the disclosure is also applicable to other aspects of semiconductor manufacturing processes, including to an electrostatic chuck.

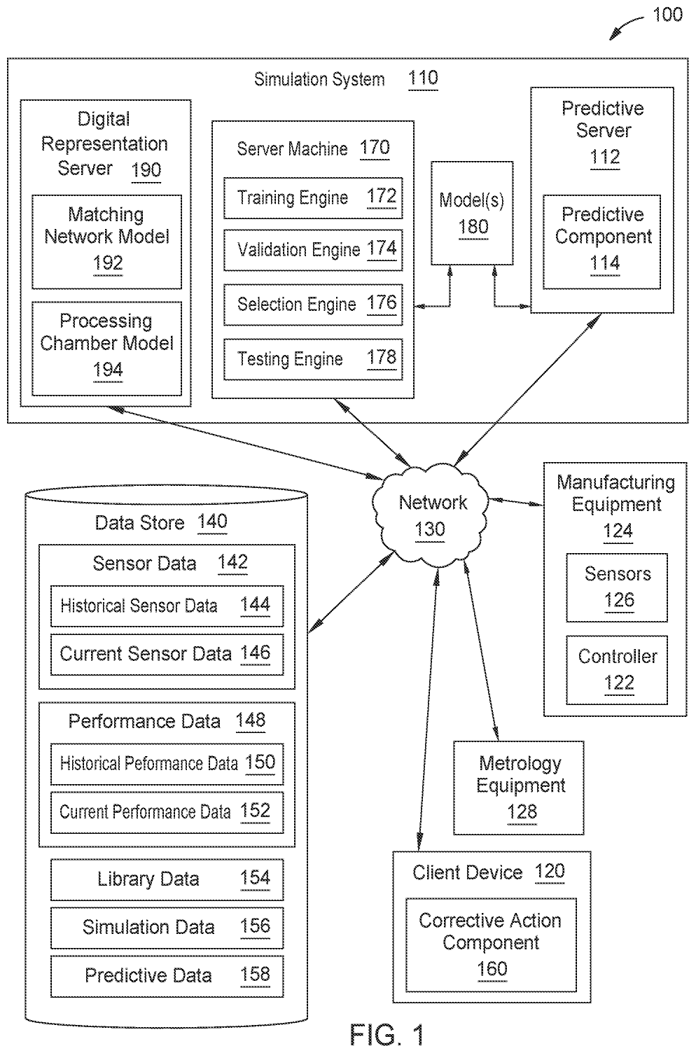

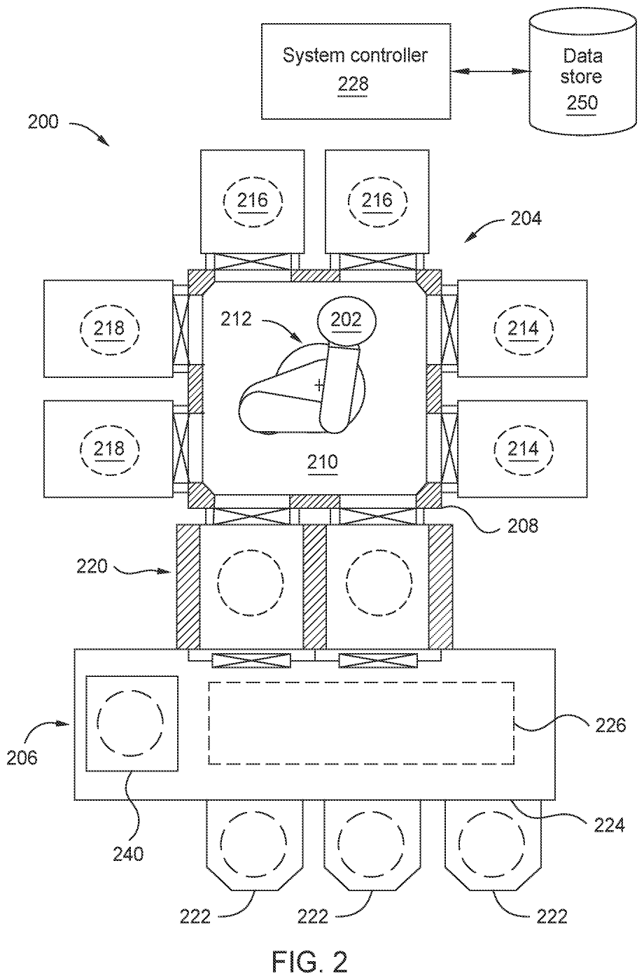

FIG. 1 is a block diagram illustrating an exemplary system architecture 100, according to certain embodiments. In some embodiments, computer system architecture 100 may be included as part of a manufacturing system for processing substrates, such as manufacturing system 200 of FIG. 2. The system architecture 100 includes a simulation system 110, a client device 120, manufacturing equipment 124, metrology equipment 128, and a data store 140. The simulation system 110 may include a digital representation server 190, a server machine 170, one or more machine learning model(s) 180, and a predictive server 112. In various embodiments, computer system architecture 100 may include fewer or additional components than those depicted in the exemplary figure.

The manufacturing equipment 124 may include sensors 126 configured to capture data for a substrate being processed at the manufacturing system, and a controller 122. In some embodiments, the manufacturing equipment 124 and sensors 126 may be part of a sensor system that includes a sensor server (e.g., field service server (FSS) at a manufacturing facility) and sensor identifier reader (e.g., front opening unified pod (FOUP) radio frequency identification (RFID) reader for sensor system). In some embodiments, metrology equipment 128 may be part of a metrology system that includes a metrology server (e.g., a metrology database, metrology folders, etc.) and metrology identifier reader (e.g., FOUP RFID reader for metrology system).

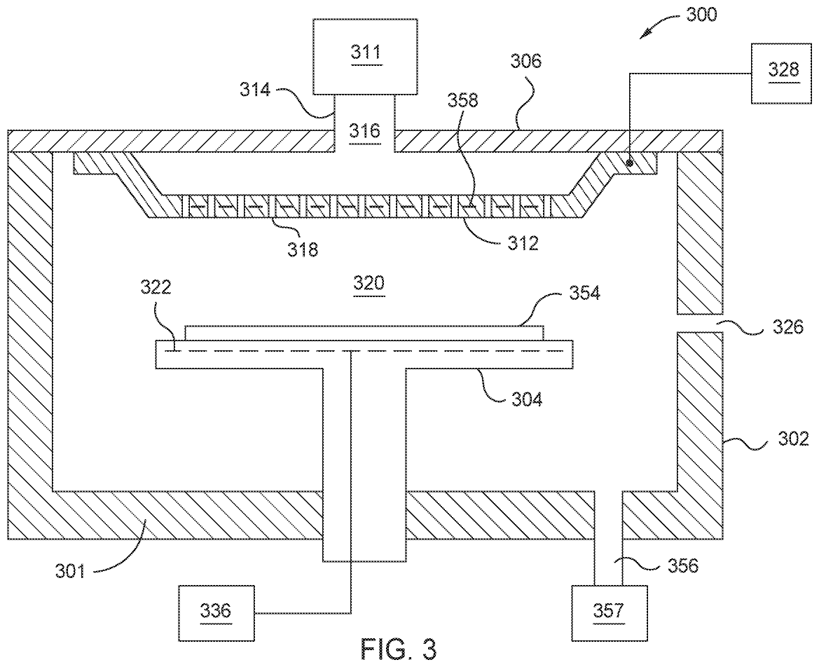

Manufacturing equipment 124 may produce products following a recipe or performing runs over a period of time via controller 122. While there may be multiple controllers for different parts of manufacturing equipment 124, a generic controller 122 is depicted in the exemplary figure for simplicity. Manufacturing equipment 124 may include a substrate measurement subsystem that includes one or more sensors 126 configured to generate spectral data and/or positional data for a substrate embedded within the substrate measurement subsystem. Sensors 126 that are configured to generate spectral data (herein referred to as spectra sensing components) may include reflectometry sensors, ellipsometry sensors, thermal spectra sensors, capacitive sensors, and so forth. In some embodiments, spectra sensing components may be included within the substrate measurement subsystem or another portion of the manufacturing system. One or more sensors 126 (e.g., eddy current sensors, etc.) may also be configured to generate non-spectral data for the substrate. Further details regarding manufacturing equipment 124 and the substrate measurement subsystem are provided with respect to FIG. 2 and FIG. 3.

In some embodiments, sensors 126 may provide sensor data associated with manufacturing equipment 124, and provide inputs to simulation system 110, and/or a controller of manufacturing equipment 124. Sensor data may include a value of one or more of temperature (e.g., heater temperature, gas temperature, and/or ambient temperature), spacing (SP), pressure, high frequency radio frequency (HFRF), voltage of electrostatic chuck (ESC), electrical current, flow rate of one or more substances present in manufacturing equipment, power, voltage, etc. Sensor data may be associated with or indicative of manufacturing parameters such as hardware parameters, including settings or components (e.g., size, type, etc.) of the manufacturing equipment 124, or process parameters of the manufacturing equipment 124. The sensor data may be provided while the manufacturing equipment 124 is performing manufacturing processes (e.g., equipment readings when processing products). The sensor data 142 may be different for each substrate.

Metrology equipment 128 may provide metrology data associated with substrates (e.g., wafers, etc.) processed by manufacturing equipment 124. The metrology data may include a value of one or more of film property data (e.g., wafer spatial film properties), dimensions (e.g., thickness, height, etc.), dielectric constant, dopant concentration, density, defects, etc. In some embodiments, the metrology data may further include a value of one or more surface profile property data (e.g., an etch rate, an etch rate uniformity, a critical dimension of one or more features included on a surface of the substrate, a critical dimension uniformity across the surface of the substrate, an edge placement error, etc.). The metrology data may be of a finished or semi-finished product. The metrology data may be different for each substrate.

Metrology equipment 128 may include on-tool metrology and off-tool metrology. On-tool metrology can include measurements performed on the devices themselves within a die or on test structures having features similar to the devices. Depending on the measurement techniques used, the test structures may include, but are not limited to, structures similar to logic or memory devices that are on the wafers. Collectively, on-tool metrology performed on devices or test structures is referred to as “on-board metrology” (OBM).

OBM can be based on optical measurements (e.g., collecting optical emission spectra in-situ from devices or test structures, or macro 2D mapping using optical targets) or other types of measurements. These optical or other measurements can be inside the chamber (in-situ), or outside the chamber (ex-situ), but still under vacuum, or, at the factory interface (not necessarily under vacuum) on a process platform that may have multiple chambers. One such example is integrated metrology, such as optical critical dimension (OCD). The term “platform” broadly encompasses a system including multiple process and/or metrology tools which are all identical or some of the tools may be different from the others. For example, a platform may have multiple process chambers performing the same process, or may have some chambers where one process (e.g., etch) is performed, and other chambers where a different process (e.g., deposition) is performed. In some other embodiments, a platform may include different types of process chambers (e.g., conductor or dielectric etch). A platform may also include metrology tools. Persons skilled in the art would appreciate that the scope of the disclosure is not limited by the configuration of the chamber and/or the platform.

Another type of on-tool metrology is referred to as “virtual metrology” (VM), which includes data collected from various sensors in the chamber or outside the chamber, but within the same platform. VM can include time traces of various process variables, such as pressure, temperature, RF power, current, voltage, flow control position, etc.

Off-tool metrology may include in-line metrology (e.g., e-beam inspection and metrology). “In-line metrology” broadly encompasses measurements that may be performed outside of a processing chamber, but without having to take the wafer out of the production line. An example of in-line metrology is scanning electron microscope (SEM), the advanced versions of which may offer high precision and broad modality. Advanced SEMs may include back-scattered electron (BSE) sensors in addition to secondary emission detectors, and ability to measure electron emission at various tilt angles and various landing energy, ranging from hundreds of electron-volt to tens of kilo electron-volts. SEMs have the capability of creating a broad database of metrology data in a non-destructive manner. SEM-based in-line metrology customized with e-beam simulation, data collection, image characterization and feature extraction as well as statistical analysis may be referred to as “customized metrology.” Advanced SEM tool may be used as the foundation of high-precision, non-destructive three-dimensional feature level profiling which is at the heart of customized metrology

Off-tool metrology may also include data available from any additional non-inline or off-line metrology, such as TEM. previously performed on a similar set of devices The digital simulation disclosed herein may use machine-learning algorithms to combine metrology data and extract meaningful relationships between metrology of dimensions of interest and various knobs that control the process.

The client device 120 may include a computing device such as personal computers (PCs), laptops, mobile phones, smart phones, tablet computers, netbook computers, network connected televisions (“smart TVs”), network-connected media players (e.g., Blu-ray player), a set-top box, over-the-top (OTT) streaming devices, operator boxes, etc. In some embodiments, the metrology data may be received from the client device 120. Client device 120 may display a graphical user interface (GUI), where the GUI enables the user to provide, as input, metrology measurement values for substrates processed at the manufacturing system.

Data store 140 may be a memory (e.g., random access memory), a drive (e.g., a hard drive, a flash drive), a database system, or another type of component or device capable of storing data. Data store 140 may include multiple storage components (e.g., multiple drives or multiple databases) that may span multiple computing devices (e.g., multiple server computers). The data store 140 may store sensor data 142, performance data 148, library data 154, simulation data 156, and predictive data 158. Sensor data 142 may include historical sensor data 144 and current sensor data 146.

Performance data 148 may include historical performance data 150 and current performance data 152. The historical sensor data 144 and historical performance data 150 may be historical data, associated with previous manufacturing runs. The current sensor data 146 may be data associated with a presently ongoing manufacturing run for which simulation data 156 and predictive data 158 are to be generated (e.g., for performing corrective actions). The current performance data 152 may also be for a presently ongoing manufacturing run, and may be used for re-training a previously trained machine learning model.

The data store 140 may store data associated with processing a substrate at manufacturing equipment 124. For example, data store 140 may store data collected by sensors 126 at manufacturing equipment 124 before, during, or after a substrate process (referred to as process data).

The performance data 148 may include data associated with the manufacturing equipment 124 and/or products produced by the manufacturing equipment 124. In some embodiments, the performance data 148 may include an indication of a lifetime of a component of manufacturing equipment 124 (e.g., time of failure), manufacturing parameters of manufacturing equipment 124, maintenance of manufacturing equipment 124, energy usage of a component of manufacturing equipment 124, variance in components (e.g., of same part number) of manufacturing equipment 124, or the like.

Performance data 148 may include an indication of variance in components (e.g., of the same type, of the same part number) of manufacturing equipment. The performance data 148 may indicate if the variance (e.g., jitter, slope, peak, etc.) contributes to product-to-product variation. The performance data 148 may indicate if a variance provides an improved wafer. The performance data 148 may be associated with a quality of products produced by the manufacturing equipment 124. The metrology equipment 128 may provide performance data 148 (e.g., property data of wafers, yield, metrology data) associated with products (e.g., processed wafers) produced by the manufacturing equipment 124. The performance data 148 may include a value of one or more of film property data (e.g., wafer spatial film properties), dimensions (e.g., thickness, height, etc.), dielectric constant, dopant concentration, density, defects, etc. The performance data 148 may be of a finished or semi-finished product. The performance data 148 may be different for each product (e.g., each processed wafer). The performance data 148 may indicate whether a product meets a threshold quality (e.g., defective, not defective, etc.). The performance data 148 may indicate a cause of not meeting a threshold quality. In some embodiments, the performance data 148 includes historical performance data 150, which corresponds to historical property data of products. The sensor data 142, performance data 148, and library data 154 may be used for supervised and/or unsupervised machine learning.

Process data can refer to historical process data (e.g., process data generated for a previous substrate processed at the manufacturing system) and/or current process data (e.g., process data generated for a current substrate processed at the manufacturing system). Data store may also store spectral data or nonspectral data associated with a portion of a substrate processed at manufacturing equipment 124. Spectral data may include historical spectral data and/or current spectral data. Current process data and/or current spectral data may be data for which predictive data is generated. In some embodiments, data store may store metrology data including historical metrology data (e.g., metrology measurement values for a prior substrate processed at the manufacturing system).

The data store 140 may also store contextual data associated with one or more substrates processed at the manufacturing system. Contextual data can include a recipe name, recipe step number, preventive maintenance indicator, operator, etc. In some embodiments, contextual data can also include an indication of a difference between two or more process recipes or process steps. For example, a first process recipe can include an operation including setting an internal temperature of a process chamber to 100° C. A second process recipe can include a corresponding operation including setting the internal temperature of the process chamber to 110° C. Contextual data can include an indication of a difference of the internal temperature of the process chamber between the first process recipe and the second process recipe.

The simulation system 110 may include digital representation server 190, server machine 170, and predictive server 112. The predictive server 112, digital representation server 190, and server machine 170 may each include one or more computing devices such as a rackmount server, a router computer, a server computer, a personal computer, a mainframe computer, a laptop computer, a tablet computer, a desktop computer, Graphics Processing Unit (GPU), accelerator Application-Specific Integrated Circuit (ASIC) (e.g., Tensor Processing Unit (TPU)), etc.

The digital representation server 190 may be an algorithmic model that simulates various parts of manufacturing equipment 124. By way of example, the digital representation server 190 may be a digital replica model (e.g., a digital twin) of a pixelated showerhead portion of the manufacturing equipment 124. The digital representation server 190 may use supervised machine learning, semi-supervised learning, unsupervised machine learning, or any combination thereof to generate a virtual representation of the physical elements and the dynamics of how the manufacturing equipment 124 operates. The digital representation server 190 may be updated via reinforcement learning using periodic updates from the sensors 126, sensor data 142, performance data 148, library data 154, and/or any other data associated with generating and maintaining the digital model of the manufacturing equipment 124.

The digital representation server 190 may include a matching network model 192 and a processing chamber model 194. The matching network model 192 may be associated with the physical elements and the dynamics of the matching network, and may include information such as target reference data or profiles, and threshold values for matching of simulations to target reference profiles. The processing chamber model 194 may be associated with the physical elements and the dynamics of the processing chamber.

In some embodiments, the digital representation server 190 may generate simulation data 156. Simulation data 156 may include data used to determine how the manufacturing equipment 124 would perform based on current or simulated parameters. The simulation data 156 may further include predicted property data of the digital model of the manufacturing equipment 124 (e.g., of products to be produced or that have been produced). The simulation data 156 may further include predicted metrology data (e.g., virtual metrology data) of the products to be produced or that have been produced. The simulation data 156 may further include an indication of abnormalities (e.g., abnormal products, abnormal components, abnormal manufacturing equipment 124, abnormal energy usage, etc.) and one or more causes of the abnormalities. The simulation data 156 may further include an indication of an end of life of a component of manufacturing equipment 124. The simulation data 156 may be all encompassing, covering any mechanical and electrical aspect of the manufacturing equipment.

The predictive server 112 may include a predictive component 114. In some embodiments, the predictive component 114 may receive simulation data 156 and current performance data 152 (e.g., processing chamber flow, processing chamber pressure, RF power, etc.) and generate output (e.g., predictive data 158) for performing a corrective action associated with the manufacturing equipment 124. In some embodiments, the predictive component 114 may use one or more trained machine learning models 180 to determine the output for performing the corrective action based on one or more of the simulation data 156, current performance data 152, and current sensor data 146.

In some embodiments, the predictive component 114 receives simulation data 156 and one or more of current performance data 152 and current sensor data 146, and provides some or all of this data as input to a trained machine learning model 180. The predictive component 114 obtains output(s) indicative of predictive data 158 from the trained machine learning model 180. The trained machine learning model 180 may include a single model, or multiple models. In some embodiments, the trained machine learning model 180 may use additional data from the data store 140 (e.g., library data 154, performance data 148, sensor data 142, etc.) or other metrology data.

In some embodiments, simulation system 110 further includes server machine 170. Server machine 170 may, using a data set generator, generate one or more data sets (e.g., a set of data inputs and a set of target outputs) to train, validate, and/or test a machine learning model(s) 180. In particular, server machine 170 can include a training engine 172, a validation engine 174, selection engine 176, and/or a testing engine 178. An engine (e.g., training engine 172, a validation engine 174, selection engine 176, and a testing engine 178) may refer to hardware (e.g., circuitry, dedicated logic, programmable logic, microcode, processing device, etc.), software (such as instructions run on a processing device, a general purpose computer system, or a dedicated machine), firmware, microcode, or a combination thereof.

The training engine 172 may be capable of training one or more machine learning models 180 using one or more sets of features associated with the training set from a data set generator. The training engine 172 may generate multiple trained machine learning models 180, where each trained machine learning model 180 corresponds to a distinct set of features of the training set (e.g., sensor data from a distinct set of sensors). For example, a first trained machine learning model may have been trained using all features (e.g., X1-X5), a second trained machine learning model may have been trained using a first subset of the features (e.g., X1, X2, X4), and a third trained machine learning model may have been trained using a second subset of the features (e.g., X1, X3, X4, and X5) that may partially overlap the first subset of features.

The validation engine 174 may be capable of validating a trained machine learning model 180 using a corresponding set of features of the validation set from data set generator. For example, a first trained machine learning model 180 that was trained using a first set of features of the training set may be validated using the first set of features of the validation set. The validation engine 174 may determine an accuracy of each of the trained machine learning models 180 based on the corresponding sets of features of the validation set. The validation engine 174 may discard trained machine learning models 180 that have an accuracy that does not meet a threshold accuracy.

In some embodiments, the selection engine 176 may be capable of selecting one or more trained machine learning models 180 that have an accuracy that meets a threshold accuracy. In some embodiments, the selection engine 176 may be capable of selecting the trained machine learning model 180 that has the highest accuracy of the trained machine learning models 180.

The testing engine 178 may be capable of testing a trained machine learning model 180 using a corresponding set of features of a testing set from data set generator. For example, a first trained machine learning model 180 that was trained using a first set of features of the training set may be tested using the first set of features of the testing set. The testing engine 178 may determine a trained machine learning model 180 that has the highest accuracy of all of the trained machine learning models based on the testing sets.

The machine learning model 180 may refer to the model artifact that is created by the training engine 172 using a training set that includes data inputs and corresponding target outputs (correct answers for respective training inputs). Patterns in the data sets can be found that map the data input to the target output (the correct answer), and the machine learning model 180 is provided mappings that captures these patterns. The machine learning model 180 may use one or more of Support Vector Machine (SVM), Radial Basis Function (RBF), clustering, supervised machine learning, semi-supervised machine learning, unsupervised machine learning, k-Nearest Neighbor algorithm (k-NN), linear regression, random forest, neural network (e.g., artificial neural network), etc.

Predictive component 114 may provide simulation data 156 and current sensor data 146 to the trained machine learning model 180 and may run the trained machine learning model 180 on the input to obtain one or more outputs. The predictive component 114 may be capable of determining (e.g., extracting) predictive data 158 from the output of the trained machine learning model 180.

For purpose of illustration, rather than limitation, aspects of the disclosure describe the training of one or more machine learning models 180 and inputting simulation data 156 and sensor data 142 into the one or more trained machine learning models 180 to determine predictive data 158. In other implementations, a heuristic model or rule-based model is used to determine predictive data 158 (e.g., without using a trained machine learning model). Predictive component 114 may monitor historical sensor data 144 and/or historical performance data 150. Any of the information described with respect to data from the data store 140 may be monitored or otherwise used in the heuristic or rule-based model.

In some embodiments, the functions of client device 120, predictive server 112, digital representation server 190, and server machine 170 may be provided by a fewer number of machines. For example, in some embodiments, digital representation server 190 and server machine 170 may be integrated into a single machine, while in some other embodiments, digital representation server 190 and server machine 170, and predictive server 112 may be integrated into a single machine. In some embodiments, client device 120 and predictive server 112 may be integrated into a single machine.

In general, functions described in one embodiment as being performed by client device 120, predictive server 112, digital representation server 190 and server machine 170 can also be performed on predictive server 112 in other embodiments, if appropriate. In addition, the functionality attributed to a particular component can be performed by different or multiple components operating together. For example, in some embodiments, the predictive server 112 may determine the corrective action based on the predictive data 158. In another example, client device 120 may determine the predictive data 158 based on output from the trained machine learning model.

In addition, the functions of a particular component can be performed by different or multiple components operating together. One or more of the predictive server 112, digital representation server 190 and server machine 170 may be accessed as a service provided to other systems or devices through appropriate application programming interfaces (API).

In embodiments, a “user” may be represented as a single individual. However, other embodiments of the disclosure encompass a “user” being an entity controlled by a plurality of users and/or an automated source. For example, a set of individual users federated as a group of administrators may be considered a “user.”

Embodiments of the disclosure may be applied to data quality evaluation, feature enhancement, model evaluation, Virtual Metrology (VM), Predictive Maintenance (PdM), limit optimization, or the like.

Although embodiments of the disclosure are discussed in terms of generating predictive data 158 to perform a corrective action in manufacturing facilities (e.g., semiconductor manufacturing facilities), embodiments may also be generally applied to characterizing and monitoring components. Embodiments may be generally applied to characterizing and monitoring based on different types of data.

The client device 120, manufacturing equipment 124, sensors 126, metrology equipment 128, predictive server 112, data store 140, digital representation server 190, and server machine 170 may be coupled to each other via a network 130 for generating predictive data 158 to perform corrective actions.

In some embodiments, network 130 is a public network that provides client device 120 with access to the predictive server 112, data store 140, and other publically available computing devices. In some embodiments, network 130 is a private network that provides client device 120 access to manufacturing equipment 124, metrology equipment 128, data store 140, and other privately available computing devices. Network 130 may include one or more Wide Area Networks (WANs), Local Area Networks (LANs), wired networks (e.g., Ethernet network), wireless networks (e.g., an 802.11 network or a Wi-Fi network), cellular networks (e.g., a Long Term Evolution (LTE) network), routers, hubs, switches, server computers, cloud computing networks, and/or a combination thereof.

The client device 120 may include a corrective action component 160. Corrective action component 160 may receive user input (e.g., via a Graphical User Interface (GUI) displayed via the client device 120) of an indication associated with manufacturing equipment 124. In some embodiments, the corrective action component 160 transmits the indication to the simulation system 110, receives output (e.g., predictive data 168) from the simulation system 110, determines a corrective action based on the output, and causes the corrective action to be implemented. In some embodiments, the corrective action component 160 obtains sensor data 142 associated with the manufacturing equipment 124 (e.g., from data store 140, etc.) and provides the sensor data 142 associated with the manufacturing equipment 124 to the simulation system 110. In some embodiments, the corrective action component 160 stores sensor data 142 in the data store 140 and the predictive server 112 retrieves the sensor data 142 from the data store 140.

In some embodiments, the predictive server 112 may store output (e.g., predictive data 168) of the trained machine learning model(s) 180 in the data store 140 and the client device 120 may retrieve the output from the data store 140. In some embodiments, the corrective action component 160 receives an indication of a corrective action from the simulation system 110 and causes the corrective action to be implemented. Each client device 120 may include an operating system that allows users to generate, view, and/or edit data (e.g., indication associated with manufacturing equipment 124, corrective actions associated with manufacturing equipment 124, etc.).

Performing manufacturing processes that result in defective products can be costly in time, energy, products, components, manufacturing equipment 124, the cost of identifying the defects and discarding the defective product, etc. By inputting sensor data 142 (e.g., manufacturing parameters that are being used or are to be used to manufacture a product), receiving output of predictive data 168, and performing a corrective action based on the predictive data 168, system architecture 100 can have the technical advantage of avoiding the cost of producing, identifying, and discarding defective products.

Performing manufacturing processes that result in failure of the components of the manufacturing equipment 124 can be costly in downtime, damage to products, damage to equipment, express ordering replacement components, etc. By inputting sensor data 142 (e.g., manufacturing parameters that are being used or are to be used to manufacture a product), receiving output of predictive data 168, and performing corrective action (e.g., predicted operational maintenance, such as replacement, processing, cleaning, etc. of components) based on the predictive data 168, system architecture 100 can have the technical advantage of avoiding the cost of one or more of unexpected component failure, unscheduled downtime, productivity loss, unexpected equipment failure, product scrap, or the like.

Corrective action may be associated with one or more of Computational Process Control (CPC), Statistical Process Control (SPC) (e.g., SPC on electronic components to determine process in control, SPC to predict useful lifespan of components, SPC to compare to a graph of 3-sigma, etc.), Advanced Process Control (APC), model-based process control, preventative operative maintenance, design optimization, updating of manufacturing parameters, feedback control, machine learning modification, or the like. In some embodiments, the corrective action may include adjusting one or more of the controllable variable tuning elements, such as knobs, as discussed in further detail herein.

In some embodiments, the corrective action includes providing an alert (e.g., an alarm to stop or not perform the manufacturing process if the predictive data 168 indicates a predicted abnormality, such as an abnormality of the product, a component, or manufacturing equipment 124). In some embodiments, the corrective action includes providing feedback control (e.g., modifying a manufacturing parameter responsive to the predictive data 168 indicating a predicted abnormality). In some embodiments, the corrective action includes providing machine learning (e.g., modifying one or more manufacturing parameters based on the predictive data 168). In some embodiments, performance of the corrective action includes causing updates to one or more manufacturing parameters.

Manufacturing parameters may include hardware parameters (e.g., replacing components, using certain components, replacing a processing chip, updating firmware, etc.) and/or process parameters (e.g., temperature, pressure, flow rate, electrical current, voltage, gas flow, lift speed, etc.). In some embodiments, the corrective action includes causing preventative operative maintenance (e.g., replace, process, clean, etc. components of the manufacturing equipment 124). In some embodiments, the corrective action includes causing design optimization (e.g., updating manufacturing parameters, manufacturing processes, manufacturing equipment 124, etc. for an optimized product). In some embodiments, the corrective action includes updating a recipe (e.g., manufacturing equipment 124 to be in an idle mode, a sleep mode, a warm-up mode, etc.).

FIG. 2 is a top schematic view of an example manufacturing system 200, according to aspects of the present disclosure. Manufacturing system 200 may perform one or more processes on a substrate 202. Substrate 202 may be any suitably rigid, fixed-dimension, planar article, such as, e.g., a silicon-containing disc or wafer, a patterned wafer, a glass plate, or the like, suitable for fabricating electronic devices or circuit components thereon.

Manufacturing system 200 may include a process tool 204 and a factory interface 206 coupled to process tool 204. Process tool 204 may include a housing 208 having a transfer chamber 210 therein. Transfer chamber 210 may include one or more processing chambers (also referred to as process chambers) 214, 216, 218 disposed therearound and coupled thereto. Processing chambers 214, 216, 218 may be coupled to transfer chamber 210 through respective ports, such as slit valves or the like. Transfer chamber 210 may also include a transfer chamber robot 212 configured to transfer substrate 202 between process chambers 214, 216, 218, load lock 220, etc. Transfer chamber robot 212 may include one or multiple arms where each arm includes one or more end effectors at the end of each arm. The end effector may be configured to handle particular objects, such as wafers.

Processing chambers 214, 216, 218 may be adapted to carry out any number of processes on substrates 202. A same or different substrate process may take place in each processing chamber 214, 216, 218. A substrate process may include atomic layer deposition (ALD), physical vapor deposition (PVD), chemical vapor deposition (CVD), etching, annealing, curing, pre-cleaning, metal or metal oxide removal, or the like. In some embodiments, a substrate process may include a combination of two or more of atomic layer deposition (ALD), physical vapor deposition (PVD), chemical vapor deposition (CVD), etching, annealing, curing, precleaning, metal or metal oxide removal, or the like. Other processes may be carried out on substrates therein. Processing chambers 214, 216, 218 may each include one or more sensors configured to capture data for substrate 202 before, after, or during a substrate process. For example, the one or more sensors may be configured to capture spectral data and/or non-spectral data for a portion of substrate 202 during a substrate process. In other or similar embodiments, the one or more sensors may be configured to capture data associated with the environment within processing chamber 214, 216, 218 before, after, or during the substrate process. For example, the one or more sensors may be configured to capture data associated with a temperature, a pressure, a gas concentration, etc. of the environment within processing chamber 214, 216, 218 during the substrate process.

A load lock 220 may also be coupled to housing 208 and transfer chamber 210. Load lock 220 may be configured to interface with, and be coupled to, transfer chamber 210 on one side and factory interface 206 on the opposite side. Load lock 220 may have an environmentally-controlled atmosphere that may be changed from a vacuum environment (wherein substrates may be transferred to and from transfer chamber 210) to an inert-gas environment at or near atmospheric-pressure (wherein substrates may be transferred to and from factory interface 206) in some embodiments. Load lock 220 may include one or more sensors to capture data associated with substrate 202 before, after, or during a substrate process at processing chambers 214, 216, 218. For example, load lock 220 may include a vibration sensor (e.g., a piezoelectric sensor) configured to detect and monitor an amount of vibration occurring within load lock 220 during a substrate process at processing chambers 214,216,218. In another example, load lock 220 may include a temperature sensor (e.g., an infrared camera) to detect and monitor a temperature of load lock 220 during a substrate process. It should be noted that, although embodiments of the present disclosure describe sensors such as a vibration sensor or a temperature sensor at load lock 220 to monitor a state of load lock 220 during a substrate process, any type of sensor can be used at any station of the manufacturing system to monitor the state and/or health of the station during a substrate process.

Factory interface 206 may be any suitable enclosure, such as, e.g., an Equipment Front End Module (EFEM). Factory interface 206 may be configured to receive substrates 202 from substrate carriers 222 (e.g., Front Opening Unified Pods (FOUPs)) docked at various load ports 224 of factory interface 206. A factory interface robot 226 (shown dotted) may be configured to transfer substrates 202 between carriers 222 (also referred to as containers) and load lock 220.

Carriers 222 may be a substrate storage carrier or a replacement part storage carrier. Factory interface 206 and/or carriers 222 may include one or more sensors (e.g., a vibration sensor, a temperature sensor, etc.) to capture data associated with substrate 202 before, after, or during a substrate process at processing chambers 214, 216, 218, in accordance with previously described embodiments.

Manufacturing system 200 may also be connected to a client device (e.g., client device 120 of FIG. 1) that is configured to provide information regarding manufacturing system 200 to a user (e.g., an operator). In some embodiments, the client device may provide information to a user of manufacturing system 200 via one or more graphical user interfaces (GUIs). For example, the client device may provide information regarding one or more modifications to be made to a process recipe for a substrate 202 via a GUI.

Manufacturing system 200 may also include a system controller 228. System controller 228 may be and/or include a computing device such as a personal computer, a server computer, a programmable logic controller (PLC), a microcontroller, and so on. System controller 228 may include one or more processing devices, which may be general-purpose processing devices such as a microprocessor, central processing unit, or the like. More particularly, the processing device may be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device may also be one or more special-purpose processing devices such as an application specific integrated circuit (ASIC), a field programmable gate array (FPGA), a digital signal processor (DSP), network processor, or the like. System controller 228 may include a data storage device (e.g., one or more disk drives and/or solid state drives), a main memory, a static memory, a network interface, and/or other components. System controller 228 may execute instructions to perform any one or more of the methodologies and/or embodiments described herein. In some embodiments, system controller 228 may execute instructions to perform one or more operations at manufacturing system 200 in accordance with a process recipe. The instructions may be stored on a computer readable storage medium, which may include the main memory, static memory, secondary storage and/or processing device (during execution of the instructions).

System controller 228 may receive data from sensors included on or within various portions of manufacturing system 200 (e.g., processing chambers 214, 216, 218, transfer chamber 210, load lock 220, etc.). In some embodiments, data received by the system controller 228 may include spectral data and/or non-spectral data for a portion of substrate 202. In other or similar embodiments, data received by the system controller 228 may include data associated with processing substrate 202 at processing chamber 214, 216, 218, as described previously. For purposes of the present description, system controller 228 is described as receiving data from sensors included within processing chambers 214, 216, 218. However, system controller 228 may receive data from any portion of manufacturing system 200 and may use data received from the portion in accordance with embodiments described herein. In an illustrative example, system controller 228 may receive data from one or more sensors for processing chamber 214, 216, 218 before, after, or during a substrate process at the processing chamber 214, 216, 218. Data received from sensors of the various portions of manufacturing system 200 may be stored in a data store 250. Data store 250 may be included as a component within system controller 228 or may be a separate component from system controller 228. In some embodiments, data store 250 may be data store 140 described with respect to FIG. 1.

Manufacturing system 200 may further include a substrate measurement subsystem 240. Substrate measurement subsystem 240 may obtain spectra measurements for one or more portions of a substrate 202 before or after the substrate 202 is processed at manufacturing system 200 using one or more metrology tools discussed herein. In some embodiments, substrate measurement subsystem 240 may obtain spectra measurements for one or more portions of substrate 202 in response to receiving a request for the spectra measurements from system controller 228. Substrate measurement subsystem 240 may be integrated within a portion of manufacturing system 200. In some embodiments, substrate measurement subsystem 240 may be integrated within factory interface 206. In other or similar embodiments, substrate measurement subsystem 240 may not be integrated with any portion of manufacturing system 200 and instead may be a stand-alone component. In such embodiments, a substrate 202 measured at substrate measurement subsystem 240 may be transferred to and from a portion of manufacturing system 200 prior to or after the substrate 202 is processed at manufacturing system 200.

Substrate measurement subsystem 240 may obtain spectra measurements for a portion of substrate 202 by generating spectral data for the portion of substrate 202. In some embodiments, substrate measurement subsystem 240 is configured to generate spectral data, nonspectral data, positional data, and other substrate property data for substrate 202 (e.g., a thickness of substrate 202, a width of substrate 202, etc.). After generating data for substrate 202, substrate measurement subsystem 240 may transmit the generated data to system controller 228. Responsive to receiving data from substrate measurement subsystem 240, system controller 228 may store the data at data store 250.

FIG. 3 depicts a schematic cross-sectional view of an exemplary processing chamber 300. As illustrated, the exemplary processing chamber 300 is configured as a Plasma Enhanced Chemical Vapor Deposition (PECVD) chamber, although in some embodiments, processing chamber 300 may be configured to perform another plasma-enhanced processing operation (such as etching or physical vapor deposition) or a processing operation that does not involve plasma (such as chemical vapor deposition). The processing chamber 300 features a chamber body 302, a substrate support 304 disposed inside the chamber body 302, and a lid 306 coupled to the chamber body 302, and enclosing the substrate support 304 in a processing volume 320. The substrate support 304 is configured to support a substrate 354 thereon during processing. The substrate 354 is provided to the processing volume 320 through an opening 326.

As illustrated, a showerhead 312 contains multiple individually tunable electrodes 358. Showerhead 312 is coupled to a power source 328 through a match circuit. In exemplary embodiments, the power source 328 is a radio frequency (RF) power source that is electrically coupled to the electrode 308. Further, the power source 328 provides between about 300 Watts and about 3,000 Watts at a frequency of about 50 kHz to about 13.6 MHz. In some embodiments, the power source 328 can be pulsed during various operations. While not expressly depicted, in some embodiments, electrodes 358 may be coupled to one or more different power sources, other than power source 328. The one or more different power sources may be RF power sources. For example, each of the electrodes 358 may be coupled to a different power source to provide a different power to each of the electrodes 358. The electrodes 358 and corresponding power sources (such as power source 328) facilitate control of a plasma formed within the processing volume 320.

The substrate support 304 contains, or is formed from, one or more metallic or ceramic materials. Exemplary metallic or ceramic materials include one or more metals, metal oxides, metal nitrides, metal oxynitrides, or any combination thereof. For example, the substrate support 304 may contain or be formed from aluminum, aluminum oxide, aluminum nitride, aluminum oxynitride, or any combination thereof.

As illustrated, one or more electrodes 322 are embedded within the substrate support 304, but alternatively may be coupled to a surface of the substrate support 304. The electrodes 322 are coupled to a power source 336. In various embodiments, the power source 336 may be DC power, pulsed DC power, radio frequency (RF) power, pulsed RF power, or any combination thereof. The power source 336 is configured to drive electrodes 322 with a drive signal to generate a plasma within the processing volume 320. It is contemplated that the drive signal may be one of a DC signal and a varying voltage signal (e.g., RF signal). Further, electrodes 322 may alternatively be coupled to the power source 328 instead of the power source 336, and the power source 336 may be omitted. In some embodiments, the power source 328 is configured to drive the showerhead electrodes 358 with drive signal(s) to generate a plasma within the processing volume 320. In one embodiment, the showerhead electrodes 358 are part of an RF field generator.

Plasma is generated in the processing volume 320 via the power source 328 and the power source 336. An RF field is created by driving at least one of the showerhead electrodes 358 and electrodes 322 with drive signals to facilitate the formation of a plasma within the processing volume 320. The presence of a plasma facilitates processing of the substrate 354, for example, the deposition of a film onto a surface of the substrate 354 or the etching of material from a surface of the substrate 354. In some embodiments, some of the electrodes 322 and/or the showerhead electrodes 358 can be individually controlled to adjust the formation of a plasma within the processing volume 320. That is, certain electrodes can be driven with more power than others, to adjust an amount or composition of plasma generated in a localized section of processing volume 320. This individual control of electrodes, or zones of electrodes, can be used to adjust a uniformity or composition of the generated plasma across the processing volume 320.

An exhaust port 356 is coupled to a vacuum pump 357. The vacuum pump 357 removes excess process gases or by-products from the processing volume 320 via the exhaust port 356 during and/or after processing.

A gas supply source 311 includes one or more gas sources. The gas supply source 311 is configured to deliver the one or more gases from the one or more gas sources through the showerhead 312 and into the processing volume 320. Each of the one or more gas sources provides a process gas such as silane, disilane, tetraethyl orthosilicate (TEOS), germane, a metal halide (such as titanium tetrachloride, tantalum pentachloride, tungsten hexafluoride), an organometallic (such as tetrakis(dimethylamido) titanium, pentakis(dimethylamido) tantalum), ammonia, oxygen (O₂), hydrogen peroxide, hydrogen, diborane, chlorine (Cl₂), sulfur hexafluoride, a hydrocarbon (generically CₓH_{y}), among others.

In some embodiments, the process gas may be ionized to form a plasma within the processing volume 320. For example, one or more of a carrier gas and an ionizable process gas are provided into the processing volume 320 to process the substrate 354. When processing a 300 mm substrate, the process gases are introduced to the processing chamber 300 at a flow rate from about 6500 sccm to about 8000 sccm, from about 100 sccm to about 10,000 sccm, or from about 100 sccm to about 1000 sccm. Alternatively, other flow rates may be utilized. In some examples, a remote plasma source can be used to deliver plasma to the processing chamber 300 and can be coupled to the gas supply source 311.

The showerhead 312 features openings 318 for admitting a process gas or gases into the processing volume 320 from the gas supply source 311. The process gases are supplied to the processing chamber 300 via the gas feed 314, and the process gases enter a plenum 316 prior to flowing through the openings 318. In some embodiments, different process gases that are flowed simultaneously during a processing operation enter the processing chamber 300 via separate gas feeds and separate plenums prior to entering the processing volume 320 through the showerhead 312.

Gas flow through the openings 318 of the showerhead 312 is regulated by one or more micro-electro-mechanical systems (MEMS devices) disposed in the showerhead 312. In some embodiments, gas flow through an individual opening 318 and/or through a cluster of openings 318 (i.e., a zone) may be regulated by a MEMS device. In some embodiments, gas flow through all openings 318 is regulated by a plurality of MEMS devices. In an example, each MEMS device regulates gas flow through one or more openings 318 such that gas flow through any single opening 318 is regulated by a corresponding MEMS device.

The regulation of gas flow by a MEMS device includes permitting a maximum flow of gas through an individual opening 318 and/or through a cluster of openings 318. The regulation of gas flow by a MEMS device includes preventing any flow of gas through an individual opening 318 and/or through a cluster of openings 318. The regulation of gas flow by a MEMS device includes controlling a flow of gas through an individual opening 318 and/or through a cluster of openings 318 such that the flow is greater than zero and less than a maximum flow of gas through the individual opening 318 and/or through the cluster of openings 318.

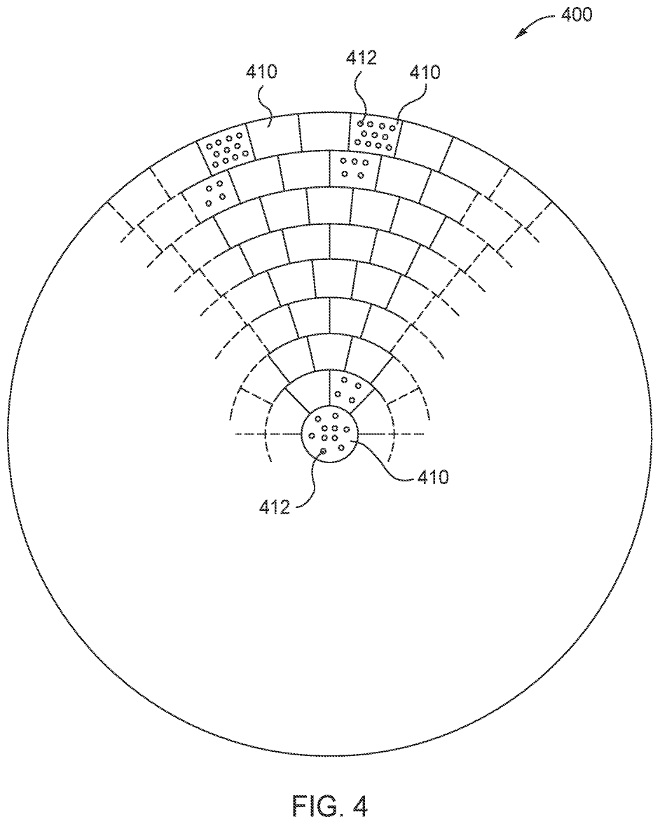

FIG. 4 is a schematic plan view of an exemplary faceplate 400 of a showerhead, such as showerhead 312 of processing chamber 300. Zones 410 are delineated on faceplate 400, where each zone 410 includes one or more openings 412 through the faceplate 400. In operation, process gas flow through the one or more openings 412 of a specific zone 410 is controlled by one or more MEMS devices associated with the specific zone 410. In operation, one or more devices, such as MEMS devices and/or heaters, are associated with each zone 410, and are controlled independently and/or in groups, as described herein. In an example, the operation of each MEMS device or heater can be controlled without changing the operating status of another MEMS device or heater associated with faceplate 400. In various embodiments, the number, size, and distribution of zones 410 may be configured according to the type of process to be conducted in processing chamber 300 and/or the specific process gas(es) to be employed.

A controller (such as controller 122 of FIG. 1) may control the gas distribution through one or more openings 412 or zones 410. The controller includes a central processing unit (CPU), a memory containing instructions, and support circuits for the CPU. The controller may be any form of a computer processor that is used in an industrial setting for controlling various chambers and equipment and/or sub-processors therein.

The memory, or non-transitory computer readable medium, is one or more of a readily available memory such as random access memory (RAM), read only memory (ROM), floppy disk, hard disk, flash drive, or any other form of digital storage, local or remote. The support circuits are coupled to the CPU for supporting the CPU (a processor). The support circuits include cache, power supplies, clock circuits, input/output circuitry and subsystems, and the like. Operations and operating parameters are stored in the memory as a software routine that is executed or invoked to turn the controller into a specific purpose controller to control the operations of any part of, or the entire showerhead 312, such as power and gas flow distribution. The controller is configured to conduct any of the operations described herein. The instructions stored on the memory, when executed, cause one or more of the operations described herein to be conducted.

The controller may be designated to control functions of any part of, or of an entirety of, processing chamber 300. As discussed herein, the controller can control operations of a pixelated showerhead by controlling at least a power distributor and/or a gas distributor of the pixelated showerhead. The power distributor controls an amount of power delivered to each power conductor of the pixelated showerhead, e.g., by controlling electrical switches of the showerhead. The gas flow distributor controls gas flow meter settings, as well as individual control of gas valves coupled to a gas supply of different gas species. The controller may control any one or more parameters controlled by gas distributor.

In some embodiments, data from any of the sensors discussed herein, and/or any sensor specifically associated with showerhead 312, may be used to provide feedback to the controller. For example, the data may include pressure data and/or temperature data.

The controller uses the data so provided as an input to process commands addressed to individual MEMS device(s) and/or group(s) of MEMS devices. In some of such embodiments, the commands prompt the individual MEMS device(s) and/or group(s) of MEMS devices to adjust a flowrate of a gas through the individual MEMS device(s) and/or group(s) of MEMS devices. In an example, such adjustments provide control of flow distribution of one or more gases through showerhead 312. In some of such embodiments, the commands prompt the individual MEMS device(s) and/or group(s) of MEMS devices to adjust a temperature of a gas flowing through the individual MEMS device(s) and/or group(s) of MEMS devices. In an example, such adjustments provide control of temperature distribution of one or more gases through showerhead 312.

The instructions in the memory of the controller can include one or more machine learning models (such as model(s) 180 of FIG. 1) that can be executed in addition to the operations described herein. As an example, a machine learning algorithm executed by the controller can optimize and alter operational parameters based on one or more sensor measurements taken by the one or more sensors. The operational parameters can include, for example, pressure, temperature, gas flow rate, valve member position, and heater status, among other process parameters.

The one or more machine learning models can account for variations in gas flow rate, gas ratios, temperature, and pressure across the showerhead 312, among other parameters, as described herein. In some embodiments, the one or more machine learning algorithms can measure any of the above parameters to determine whether an appropriate quantity of a process gas at an appropriate pressure and an appropriate temperature is being delivered to the appropriate regions of a processing volume according to a prescribed operation. In some embodiments, the one or more machine learning algorithms can prompt the controller to initiate corrective action in order to adjust the quantity, pressure, or temperature of a process gas being delivered to a prescribed region of a processing volume.

The operational flexibilities described above facilitated by showerheads of the present disclosure are not provided by conventional showerheads. Conventional showerheads typically are configured for achieving an optimal distribution of a specific process gas by having a given number of openings of particular sizes arranged in a specific pattern. However, the number, sizing, and arrangement of openings that provides for an optimal distribution of one process gas do not necessarily provide for an optimal distribution of a different process gas. In contrast, showerheads of the present disclosure provide for the relative flow rate of any process gas through an opening, or a cluster of openings, to be tailored to provide for an optimal distribution of any process gas in a processing chamber.

The operational flexibilities facilitated by showerheads of the present disclosure provide time and cost efficiencies compared to conventional operations. For example, some conventional processing sequences involve performing a first operation on a substrate with a first process gas in a first processing chamber, then transferring the substrate to a second processing chamber, then performing a second operation on the substrate with a second, different, process gas. In contrast, processing chambers incorporating showerheads of the present disclosure may be used to perform both the first operation with the first process gas and then the second operation with the second process gas. Thus, the need for the second processing chamber is alleviated, as is the time taken to transfer the substrate between the processing chambers.

Furthermore, the operational flexibilities facilitated by showerheads of the present disclosure provide efficiencies in inventory management compared to conventional operations. The use of showerheads of the present disclosure reduces or eliminates the need to stock different showerheads that are configured for use with different process gases for different process operations.

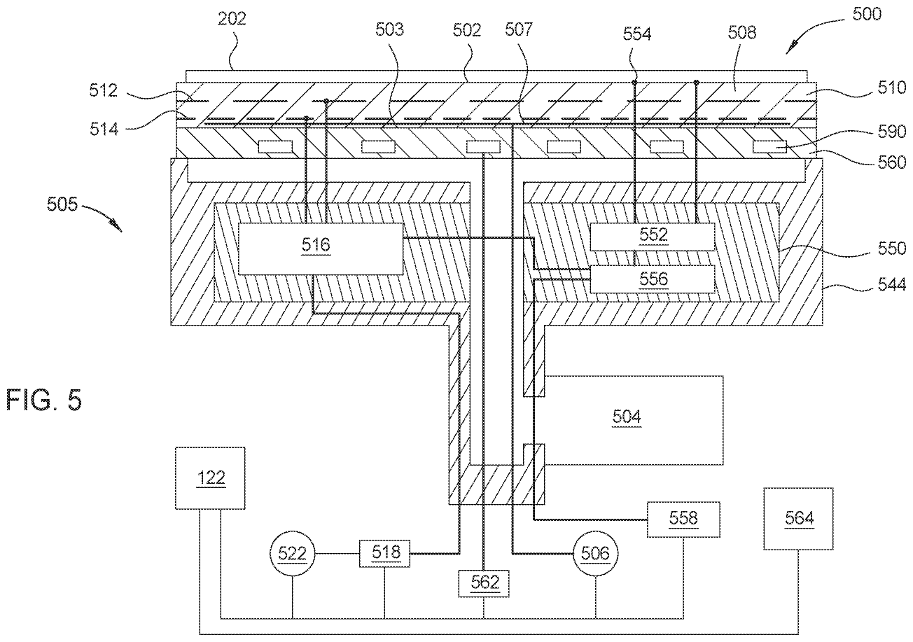

FIG. 5 is a partial cross-sectional schematic side view detailing portions of a substrate support assembly 500 configured to provide azimuthal tuning of a temperature profile across the substrate support assembly. The azimuthal tuning of the temperature profile across the substrate support assembly 500 may be controlled by software routines running on the controller 122. The software routines may also or alternately be stored and/or executed by a second controller (not shown) that is located remotely from the multi-chamber vacuum processing system, such as at the processing chamber 300 or an advance process controller (APC) 564.

The substrate support assembly 500 generally includes at least a substrate support 510. The substrate support 510 may be a vacuum chuck, an electrostatic chuck, a susceptor, or other work-piece support surface. In one embodiment, the substrate support 510 is an electrostatic chuck and will be described hereinafter as the electrostatic chuck 510. The substrate support assembly 500 may also include a cooling base 560. The cooling base 560 may alternately be separate from the substrate support assembly 500. The substrate support assembly 500 may be removably coupled to a support pedestal 505. The support pedestal 505 may include a pedestal base 544. The substrate support assembly 500 may be periodically removed from the support pedestal 505 to allow for refurbishment of one or more components of the substrate support assembly 500.

The electrostatic chuck 510 has a mounting surface 503 and a work-piece support surface 502 opposite the mounting surface 503 where the substrate 202 is removably disposed upon the work-piece support surface 502. The electrostatic chuck 510 generally includes a chucking electrode 507 embedded in a dielectric body 508. Although the chucking electrode 507 is shown proximate the mounting surface 503 of the electrostatic chuck 510, the chucking electrode 507 may be embedded in other portions of the electrostatic chuck 510, such as just under the work-piece support surface 502. The chucking electrode 507 may be configured as a mono polar or bipolar electrode, or other suitable arrangement. The chucking electrode 507 is coupled through an RF filter 504 to a chucking power source 506 which provides a RF or DC power to electrostatically secure the substrate 202 to the work-piece support surface 502 of the electrostatic chuck 510. The RF filter 504 prevents RF power utilized to form a plasma within the processing chamber (such as processing chamber 300 from FIG. 3) from damaging electrical equipment or presenting an electrical hazard outside the chamber.

The dielectric body 508 of the electrostatic chuck 510 may be fabricated from a ceramic material, such as AlN or Al₂O₃. Alternately, the dielectric body 508 may be fabricated from a polymer, such as polyimide, polyetheretherketone, polyaryletherketone and the like. Heaters may be embedded within the dielectric body 508. The dielectric body 508 may include one or more main resistive heaters 512 and/or a plurality of spatially tunable heaters 514. The main resistive heaters 512 may be provided to elevate the temperature of the substrate support assembly 500 to a temperature for conducting chamber processes, such as processing the substrate 202 and/or cleaning the interior of the processing chamber 300. The main resistive heater 512 may be configured to provide any one or more laterally separated heating zones, for example, a plurality of concentric ring-shaped zones.

The spatially tunable heaters 514 are complimentary to the main resistive heaters 512 and configured to adjust the localized temperature of the electrostatic chuck 510 in a plurality of discrete locations (or zones) within any one or more of a plurality of laterally separated heating zones defined by the main resistive heaters 512. For example, the spatially tunable heaters 514 may be arranged in a polar array, Cartesian grid of columns and rows, a hexagonal grid, or other suitable matrix. The spatially tunable heaters 514 thus provide localized adjustments to the temperature profile of the substrate 202 placed on the substrate support assembly 500. Thus, the main resistive heaters 512 operate to maintain the temperature profile of the work-piece support surface 502 on a globalized macro scale, while the spatially tunable heaters 514 operate to adjust the temperature at discreet locations of the temperature profile of the work-piece support surface 502 on a localized micro scale.

The main resistive heaters 512 and spatially tunable heaters 514 are coupled through an RF filter 518 to a heater power source 522. The heater power source 522 may provide 900 watts or more power to the heaters 512, 514. The controller 122 (which may be the same as controller 122 of FIG. 1 in some embodiments) may control the operation of the heater power source 522, which is generally set provide power to individual heaters 512, 514 for heating the substrate 202 to a predefined temperature profile. In one embodiment, the main resistive heaters 512 include laterally separated heating zones, wherein the controller 122 enables one zone of the main resistive heaters 512 or even single spatially tunable heaters 514 to be preferentially heated relative to adjacent heaters 512, 514. In some embodiments, each spatially tunable heater 514 may be independently controlled to provide a temperature different than that of another one of the spatially tunable heaters 514. In some embodiments, a plurality, such as at least two and as many as all, of the spatially tunable heaters 514 are independently and simultaneously powered to provide a temperature profiled which is very stable and does not jump in around, which results in a steady and easily controlled temperature profile, which contributes to enhanced uniformity and predictability of substrate processing results.

The electrostatic chuck 510 may include one or more temperature sensors 554. The temperature sensors 554 may measure temperature at a plurality of discrete locations on the work-piece support surface 502. The temperature sensors 554 may provide temperature feedback information to the controller 122 for controlling the power applied by the heater power source 522 to the main resistive heaters 512 and the spatially tunable heaters 514. Additionally, the feedback information may be used to control the operations of the cooling base 560.

The electrostatic chuck 510 may be disposed on the temperature controlled cooling base 560. The temperature controlled cooling base 560 is coupled to a heat transfer fluid source 562. The heat transfer fluid source 562 provides a heat transfer fluid, such as a liquid, gas or combination thereof, which is circulated through one or more conduits 590 disposed in the cooling base 560. The controller 122 may control the fluid flowing through isolated neighboring conduits 590 to enabling local control of the heat transfer between the electrostatic chuck 510 and different regions of the cooling base 560, which assists in controlling the lateral temperature profile of the substrate 202.

The pedestal base 544 is disposed below the cooling base 560 and is configured to accommodate a plurality of driving mechanisms configured to raise and lower a plurality of lifting pins. Additionally, the pedestal base 544 is configured to accommodate the plurality of fluid connections from the electrostatic chuck 510 and the cooling base 560. The pedestal base 544 is also configured to accommodate the plurality of electrical connections from the electrostatic chuck 510. The myriad of connections, for example fluids, electrical, data signals, may run externally or internally of the substrate support assembly 500.

The system controller 122 may include a controller board 550 that may be disposed in the pedestal base 544. Alternately, the controller board 550 may be disposed elsewhere inside or outside the substrate support assembly 500. The controller board 550 may have a pulse width modification (PWM) heater controller 516. The controller board 550 may also have an optical communication interface board 556. The controller board 550 also may optionally have a temperature sensor controller 552.

The temperature sensor controller 552 may be communicatively coupled to the temperature sensors 554 for measuring the substrate 202 temperature. The temperature sensor controller 552 may convert the signals from the temperature sensors 554 to actual temperature readings in discrete locations about the work-piece support surface 502. The controller board 550 also may optionally have a metrology controller (not shown) for determining the thickness of a substrate 202 disposed on the work-piece support surface 502.

The PWM heater controller 516 may connect to the heaters 512, 514. The PWM heater controller 516 may modify the power coming from the heater power source 522 to the individual heaters 512, 514. The PWM heater controller 516 may be programmed and calibrated by measuring the temperature at each spatially tunable heater 514. That is, each spatially tunable heater 514 has its own independent PWM control. The PWM heater controller 516 may control the temperature by adjusting the power parameters for individual spatially tunable heater 514. For example, 100 percent power to one of the spatially tunable heater 514 may result in about 5 degrees Celsius of heat output for increasing the temperature set by the main heater for the surface location above the spatially tunable heater 514. Additionally, 20 percent power to one or more of the spatially tunable heaters 514 may result in about a 1 degree Celsius heat output for increasing the temperature set by the main heater for the surface location above the spatially tunable heater 514. The power may be reduced to 20% for several of the spatially tunable heater 514 and maintained at that level throughout a processing operation. Additionally, the PWM heater controller 516 may operate one or more spatially tunable heaters 514 at a first power level, for example 80 percent, while simultaneously operating one or more separate spatially tunable heaters 514 at a second power level, for example about 20 percent. In one embodiment, the temperature may be regulated with incremental power increases to the spatially tunable heaters 514. For example, a temperature rise may be obtained with a percentage increase, for example 9% increase, in the power supplied to the spatially tunable heater 514 during the course of a process. In another embodiment, the temperature may be regulated by cycling the spatially tunable heater 514 on and off, while the other tunable heaters 514 also cycled on and off, either in-phase, or out of phase. In yet another embodiment, the temperature may be regulated by a combination of adjusting the power levels, cycling and incrementally adjusting the power to the spatially tunable heater 514 as needed to maintain a desired temperature profile.

A temperature map may be obtained by varying the heat output of each individual spatially tuning heater 514 all at one instance. The map may correlate the CD or substrate temperature profile to the power distribution curve for each spatially tunable heater 514. Thus, the spatially tunable heater 514 may be used to generate a temperature profile on the substrate based on a program regulating power settings for the individual spatially tunable heater 514. The logic can be placed directly in the PWM heater controller 516 or in an externally connected controller, such as the controller 122. Thus, the PWM heater controller 516 is configured to independently control an output of one of the plurality of spatially tunable heaters 514 relative to another of the plurality of spatially tunable heaters 514 as well as the main resistive heaters 512.

The optical communication interface board 556 may interface with the PWM heater controller 516. The optical communication interface board 556 may also interface with other controllers such as the temperature sensor controller 552. The optical communication interface board 556 may have an optical connection to an optical converter 558. The optical interface board 556 may send an optical signal to the optical converter 558 for communicating with the controller 122. Thus, communication between the PWM heater controller 516 and the controller 122 may be performed by optical signals which are free of damaging RF energy. For example, the controller 122 may send a signal to control the heat output from one or more of the spatially tunable heaters 514 for adjusting the temperature profile of the substrate 202 disposed on the electrostatic chuck 510. The signal instruction from the controller 122 may enter the optical converter 558 for transmission to the optical communication interface board 556 before delivery of the instruction to the PWM heater controller 516 for controlling the heating profile of the substrate 202 during processing. A benefit of the optical communication interface board 556 is the ability to prevent RF power from traveling through control circuitry leaving the substrate support assembly 500.

The temperature of the surface for the substrate 202 in the processing chamber 300 may be influenced by the evacuation of the process gases by the pump, the slit valve door, the plasma and other factors. The controller 122 may have a temperature profile map for the substrate 202 for obtaining high quality processing results. The controller 122 may receive input from the metrology equipment or other processing equipment to correct for deviation or adverse trends in the process results of the substrate 202. For example, one area of the substrate 202 may etch faster than another area of the substrate 202. The controller 122 may signal the spatially tunable heaters 514 to adjust the surface temperature of the substrate 202 in the area deviating in the etch rate. The controller 122 may activate the spatially tunable heaters 514 in a pattern similar in shape to these areas. The spatially tunable heaters 514 improve the temperature profile of the surface of the substrate 202 produced by the main resistive heaters 512 by reducing variations in the temperature profile to about +/−0.3 degrees Celsius. The temperature profile may be made uniform or to vary precisely in a predetermined manner across regions of the substrate 202 through the use of the spatially tunable heaters 514 to obtain desired results. The use of independently controllable spatially tunable heaters 514 to smooth out or correct the temperature profile generated by the main resistive heaters 512 enable control of the local temperature uniformity across the substrate to very small tolerances, thereby enabling precise process and CD control when processing the substrate 202. Additionally, the small size and high density of the spatially tunable heaters 514 relative to the main resistive heaters 512 enables temperature control at specific locations on the substrate support assembly, substantially without affecting the temperature of neighboring areas, thereby allowing local hot and cool spots to be compensated for without introducing skewing or other temperature asymmetries.

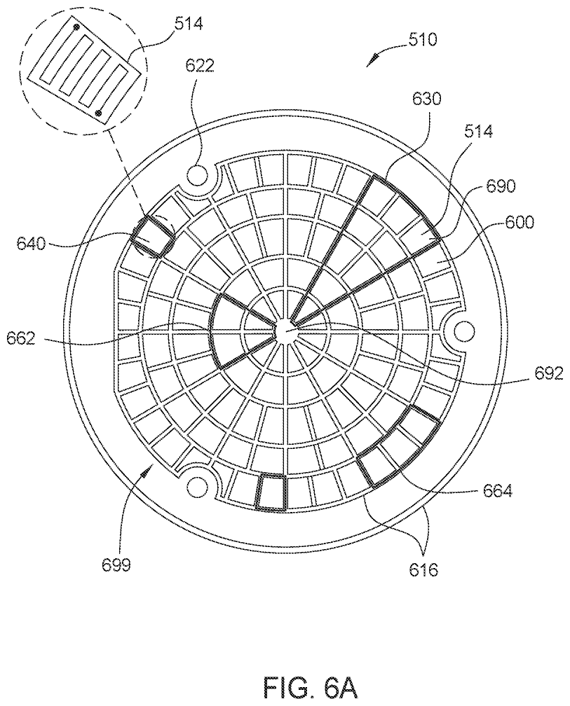

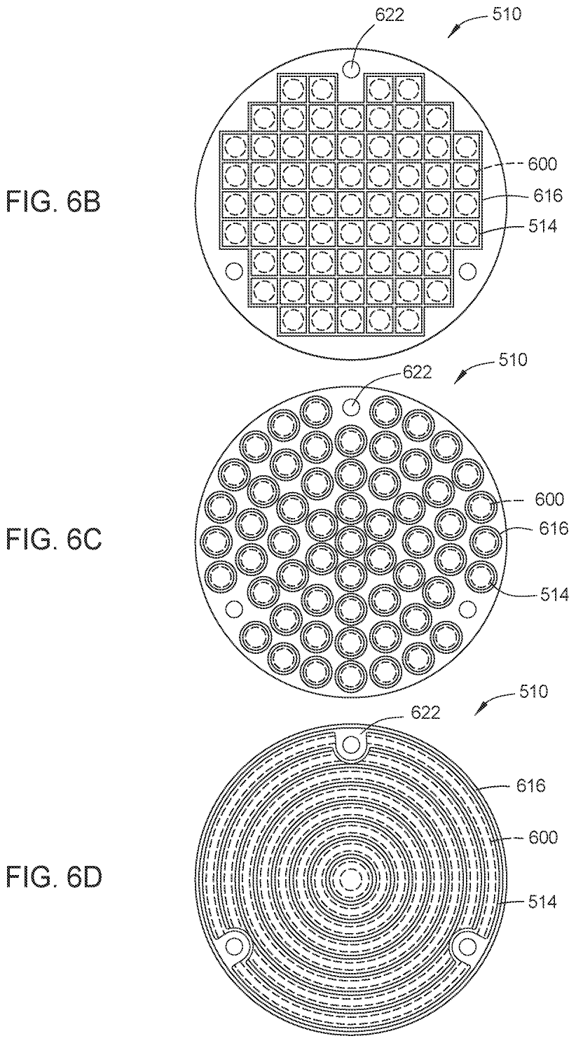

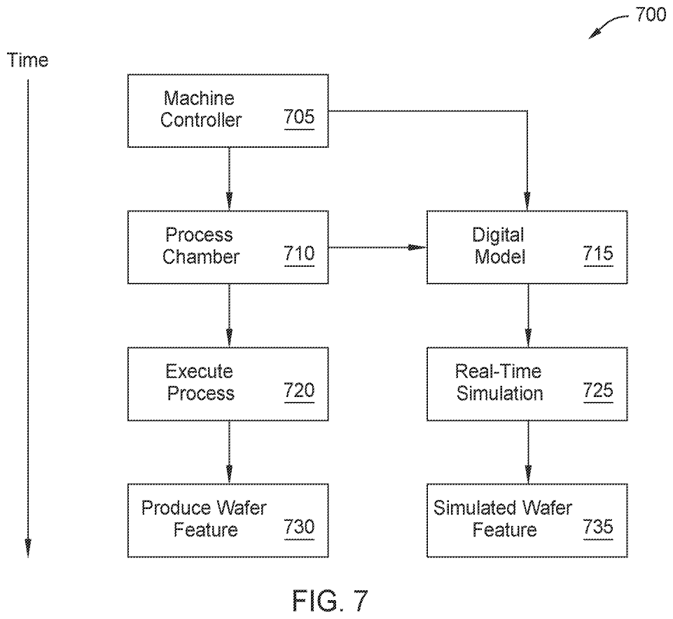

It is contemplated that there may be about 200 to about 400, or even more spatially tunable heaters 514 in a given embodiment of a substrate support assembly 500 configured for use with a 300 mm substrate. Even more spatially tunable heaters 514 are contemplated for substrates of 450 mm or larger. Exemplary distribution of the spatially tunable heaters 514 are described further below with reference to FIGS. 6A-6D.

FIGS. 6A-6D are top views of the electrostatic chuck 510 illustrating example layouts of cells 690 having the spatially tunable heaters 514 therein. FIG. 6A is a top view of the electrostatic chuck 510 of FIG. 5, according to one embodiment. FIGS. 6B-6D are top views of the electrostatic chuck 510 of FIG. 5, according to alternate embodiments. The cells 690 may have material (or gaps) which act as a thermal choke 616 between adjacent cells 690. The thermal chokes 616 separate and reduce conduction between adjacent cells 600. Thus, by individually and independently controlling the power provided to each spatially tunable heaters 514 in each cell 690, a localized approach is achieved for controlling the temperature which enables specific points of the substrate 202 to be heated or cooled, thereby enabling a truly addressable lateral temperature profile tuning and control of the surface of the substrate 202.

Referring now to FIG. 6A, the thermal choke 616 is disposed between each neighboring cell 690. Each cell 690 has associated therewith at least one of the spatially tunable heaters 514. The number of cells 690 shown is for illustration only, and any number of embodiments may have substantially more (or less) cells 690. The number of spatially tunable heaters 514 may be at least an order of magnitude greater than the number of main resistive heaters 512. The number of spatially tunable heaters 514 located across the substrate support assembly 500 may easily be in excess of several hundred.

The spatially tunable heaters 514 may be configured in a pattern 699 to efficiently generate a heat profile along the surface of the electrostatic chuck 510. The pattern 699 may be symmetric about a midpoint 692, while providing clearance in and around holes 622 for lift pins or other mechanical, fluid or electrical connections. Each spatially tunable heater 514 may be controlled by the controller 122 through the PWM controller 516 (FIG. 5). The PWM controller 516 may turn on a single spatially tunable heater 514 defining a local area 640; or a plurality of spatially tunable heaters 514 grouped to define an inner wedge 662, a perimeter group 664, a pie shaped area 630, or other desired geometric configuration, including non-contiguous configurations for determining a desired temperature profile. In this manner, temperature can be precisely controlled at independent locations along the surface of the electrostatic chuck 510, such independent locations not limited to concentric rings, or other center to edge configurations known in the art. Although the pattern 699 shown is comprised of discontinuous smaller units, the pattern 699 may alternatively have larger and/or smaller units, extend to the edge, or have other forms. In the embodiment depicted in FIG. 6A, the pattern 699 of spatially tunable heaters 514 are arranged in a polar array about the midpoint 692, which in some embodiments, may coincide with the centerline of the electrostatic chuck 510.

FIG. 6B is a top view of the electrostatic chuck 510 depicted in FIG. 5, according to another embodiment. The spatially tunable heaters 514 are arranged in the form of a grid, thus defining an array of temperature control cells 690 also arranged in the grid pattern. Although the grid pattern of spatially tunable heaters 514 is shown as an X/Y (Cartesian) grid comprised of rows and columns, the grid pattern of spatially tunable heaters 514 may alternatively have some other uniformly packed form, such as a hexagon close pack. It should be appreciated, as discussed supra, the spatially tunable heaters 514 may be activated in groups or singularly.

FIG. 6C is a top view of the electrostatic chuck 510 depicted in FIG. 5, according to another embodiment. FIG. 6C illustrates a plurality of spatially tunable heaters 514 arranged in a polar array. Optionally, one or more of thermal chokes 616 may be disposed between the spatially tunable heaters 514. The polar array pattern of the spatially tunable heaters 514 defines the neighboring cells 690, which are thus also be arranged in a polar array. Optionally, thermal chokes 616 may be utilized to isolate each cell 690 from the adjacent cell 690.

FIG. 6D is a top view of the electrostatic chuck 510 depicted in FIG. 5, according to another embodiment. FIG. 6D illustrates a plurality of spatially tunable heaters 514 arranged in concentric channels. The concentric channel pattern of the spatially tunable heaters 514 may be optionally separated by thermal chokes 616. It is contemplated that the spatially tunable heaters 514 and cells 690 may be arranged in other orientations.

The number and density of the spatially tunable heaters 514 contribute to the ability for controlling the temperature uniformity across the substrate to very small tolerances which enables precise process and CD control when processing the substrate 202. Additionally, individual control for one of the spatially tunable heaters 514 relative to another spatially tunable heater 514 enables temperature control at discrete locations along the surface of the substrate support assembly 500 without substantially affecting the temperature of neighboring or adjacent areas of the surface. This feature allows local hot and cool spots to be compensated for without introducing skewing or other temperature asymmetries. The spatially tunable heaters 514 may have an individual temperature range between about 0.0 degrees Celsius and about 10.0 degrees Celsius with the ability to control the temperature rise in increments of about 0.1 degrees Celsius. In one embodiment, the plurality of spatially tunable heaters 514 in the substrate support assembly 500 in conjunction with the main resistive heaters 512 have demonstrated the ability to control the temperature uniformity of a substrate 202 processed thereon to less than about ±0.3 degrees Celsius. Thus, the spatially tunable heaters 514 allow both lateral and azimuthal tuning of the lateral temperature profile of the substrate 202 processed on the substrate support assembly 500.

The heaters 514, 512 may be controlled by a software routine. The software may incorporate current substrate CD measurements and process results along with the process recipes and other parameters to tune the temperature profile for the substrate 202 undergoing processing in the processing chamber 300

FIG. 7 depicts a simplified timing diagram 700 for a physical manufacturing process with concurrent real-time simulation. In the timing diagram 700, a machine controller 705 inputs process parameters into a process chamber 710 for a particular manufacturing process. As discussed herein, the manufacturing process may be a process using a pixelated showerhead, electrostatic chuck, or a process that can generate pixelated plasma. The machine controller 705 also simultaneously sends the process parameters to a digital twin model 715 of the process chamber. Sensor data, as discussed herein, is also transmitted from the process chamber 710 to the digital twin model 715.

The process chamber then executes a manufacturing process at block 720. Simultaneously, the digital twin model 715 performs a real-time simulation 725 of the process under execution, based at least in part some or all of the sensor inputs received from the process chamber, a model of the process chamber, one or more trained machine learning models, and metrology data. Finally, the process chamber produces a wafer feature at block 730. Concurrently, the digital twin model produces a simulation of the produced wafer feature at block 735. The simulation of the produced wafer feature should match almost exactly with the actual produced wafer feature. In this way, a digital replica of a process chamber is able to generate a computer simulation of a manufacturing process, concurrently with the operation of that manufacturing process.

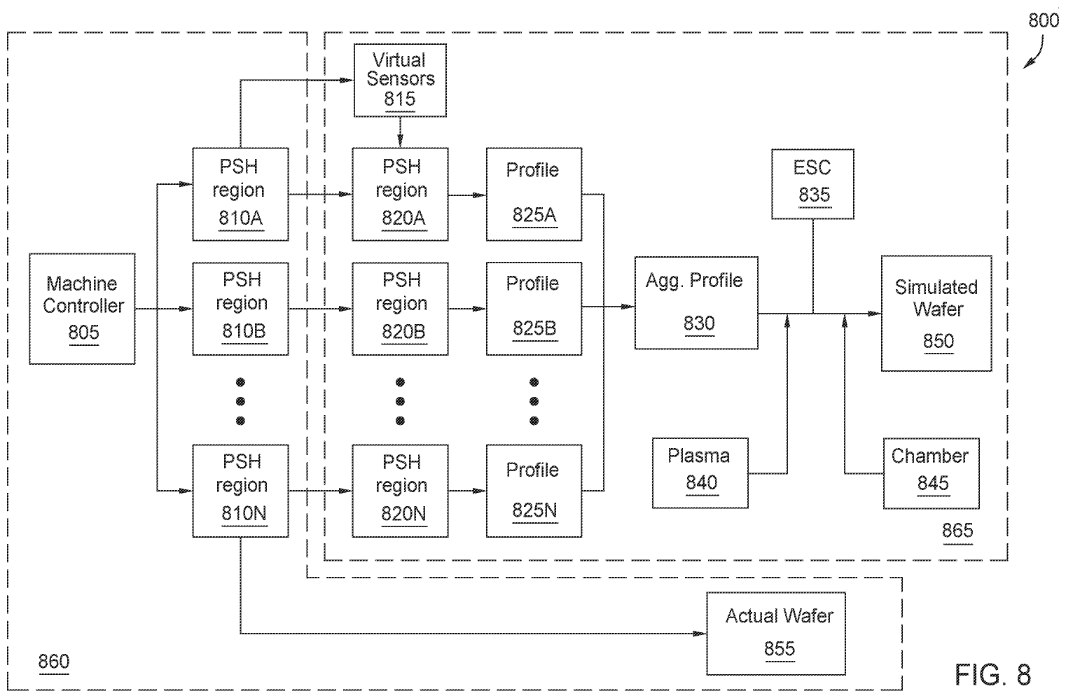

FIG. 8 depicts an exemplary environment 800 within which embodiments of the present disclosure are practiced for a concurrent process run with simulations. Environment 800 depicts a physical process flow 860 occurring simultaneously with a digital twin flow 865. While these specific flow operations are shown in the figure for illustrative purposes, other operations may also be present in other embodiments.

In the physical process flow, a machine controller 805 controls at least one aspect of at least one pixelated showerhead (PSH) region. As discussed herein, a PSH region may be any one or more nozzles located on a faceplate of a showerhead, also sometimes referred to herein as “zones”. In the exemplary FIG. 8, there can be any N number of PSH regions (e.g., 810A, 810B, through 810N). The physical process flow 860 ends with the production of an actual processed wafer 855.

The digital twin flow 865 may operate in substantially real-time, simultaneously with the physical process flow 860. In the digital twin flow 865, virtual sensors 815 are used to generate a simulation of each pixelated showerhead region, PSH regions 820A, 820B, through 820N. Further, a gas profile for each of these PSH regions is generated as profile 825A, 825B, through 825N. The gas profiles represent a profile of one or more process gases that are present at the specific regions of the processing chamber. In other embodiments, a plasma profile representing an amount of plasma present at the specific regions of the processing chamber can be generated. Further, other types of profiles for each region can be generated at this step. The individual regional profiles are combined into an aggregate profile 830 representing the presence of a process gas across the substrate.

The aggregate profile 830 is combined with simulated data regarding the plasma 840, the electrostatic chuck 835, and the chamber itself 845. These inputs combined are used to generate a simulated processed wafer 850, which is a computer simulation of actual processed wafer 855 generated by the physical process. In various embodiments, the simulated processed wafer 850 is generated substantially simultaneously as the actual processed wafer 855.

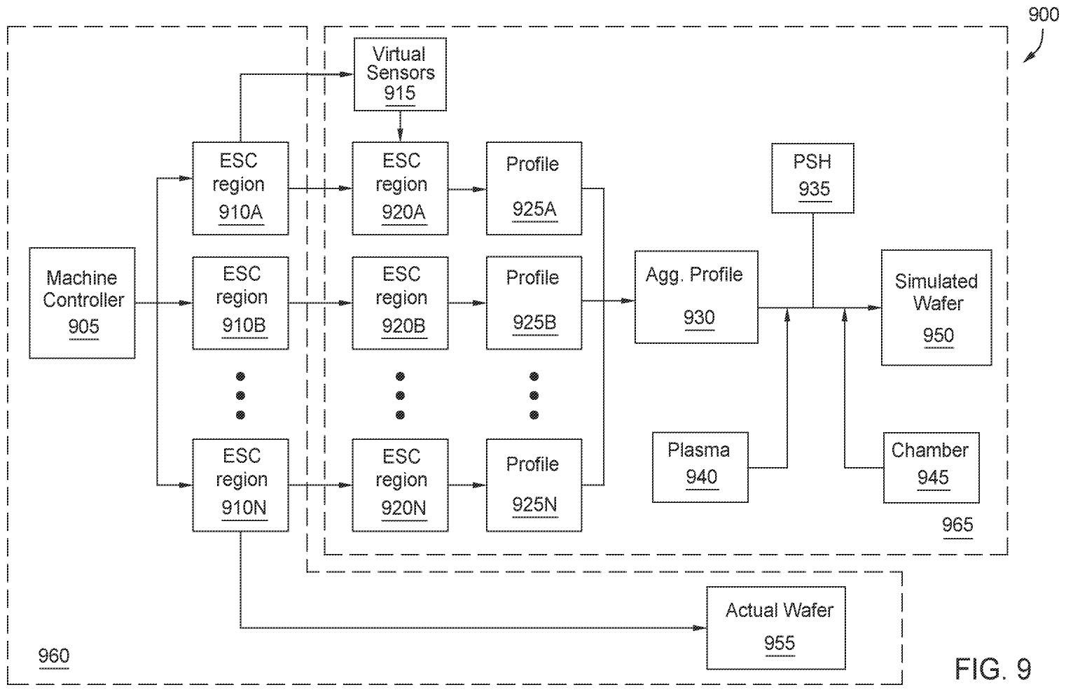

FIG. 9 depicts an exemplary environment 900 within which embodiments of the present disclosure are practiced for a concurrent process run with simulations. Environment 900 depicts a physical process flow 960 occurring simultaneously with a digital twin flow 965. While these specific flow operations are shown in the figure for illustrative purposes, other operations may also be present in other embodiments.

In the physical process flow, a machine controller 905 controls at least one aspect of at least one electrostatic chuck (ESC) region. As discussed herein, an ESC region may be any one or more heaters located on an ESC, also sometimes referred to herein as “zones”. In the exemplary FIG. 9, there can be any N number of ESC regions (e.g., 910A, 910B, through 910N). The physical process flow 960 ends with the production of an actual processed wafer 955.

The digital twin flow 965 may operate in substantially real-time, simultaneously with the physical process flow 960. In the digital twin flow 965, virtual sensors 915 are used to generate a simulation of each ESC region, ESC regions 920A, 920B, through 920N. Further, a temperature profile for each of these ESH regions is generated as profile 925A, 925B, through 925N. The temperature profiles represent a profile of temperature at one or more locations of the specific regions of the processing chamber. In other embodiments, a plasma profile representing an amount of plasma present at the specific regions of the processing chamber can be generated. Further, other types of profiles for each region can be generated at this step. The individual regional profiles are combined into an aggregate profile 930 representing a temperature across the substrate.

The aggregate profile 930 is combined with simulated data regarding the plasma 940, the pixelated showerhead 935, and the chamber itself 945. These inputs combined are used to generate a simulated processed wafer 950, which is a computer simulation of actual processed wafer 955 generated by the physical process. In various embodiments, the simulated processed wafer 950 is generated substantially simultaneously as the actual processed wafer 955.

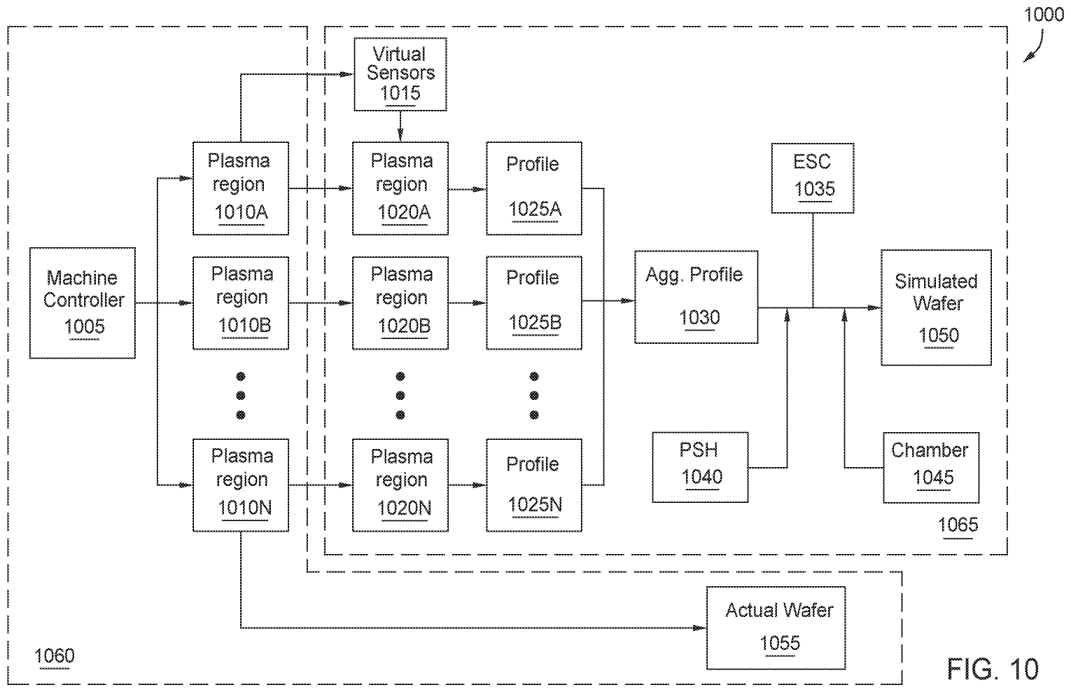

FIG. 10 depicts an exemplary environment 1000 within which embodiments of the present disclosure are practiced for a concurrent process run with simulations. Environment 1000 depicts a physical process flow 1060 occurring simultaneously with a digital twin flow 1065. While these specific flow operations are shown in the figure for illustrative purposes, other operations may also be present in other embodiments.

In the physical process flow, a machine controller 1005 controls at least one aspect of at least one plasma region. As discussed herein, plasma generation in the process chamber may be driven by one or more individually controlled electrodes, such as electrodes 358 of FIG. 3. One or more electrodes may comprise a group of electrodes controlled together, also sometimes referred to herein as “zones” of electrodes. In the exemplary FIG. 10, there can be any N number of plasma regions (e.g., 1010A, 1010B, through 1010N). The physical process flow 1060 ends with the production of an actual processed wafer 1055.

The digital twin flow 1065 may operate in substantially real-time, simultaneously with the physical process flow 1060. In the digital twin flow 1065, virtual sensors 1015 are used to generate a simulation of each plasma region, plasma regions 1020A, 1020B, through 1020N. Further, a profile for each of these plasma regions is generated as profile 1025A, 1025B, through 1025N. In one embodiment, the profile is of a composition of the plasma in the region. In another embodiment, the profile is of a density of plasma in the region. In further embodiments, the profile can be of any parameter associated with the plasma. The profiles represent a condition of the parameter in the specific regions of the processing chamber. The individual regional profiles are combined into an aggregate profile 1030 representing a condition of the plasma across the substrate.

The aggregate profile 1030 is combined with simulated data regarding the PSH 1040, the ESC 1035, and the chamber itself 1045. These inputs combined are used to generate a simulated processed wafer 1050, which is a computer simulation of actual processed wafer 1055 generated by the physical process. In various embodiments, the simulated processed wafer 1050 is generated substantially simultaneously as the actual processed wafer 1055.

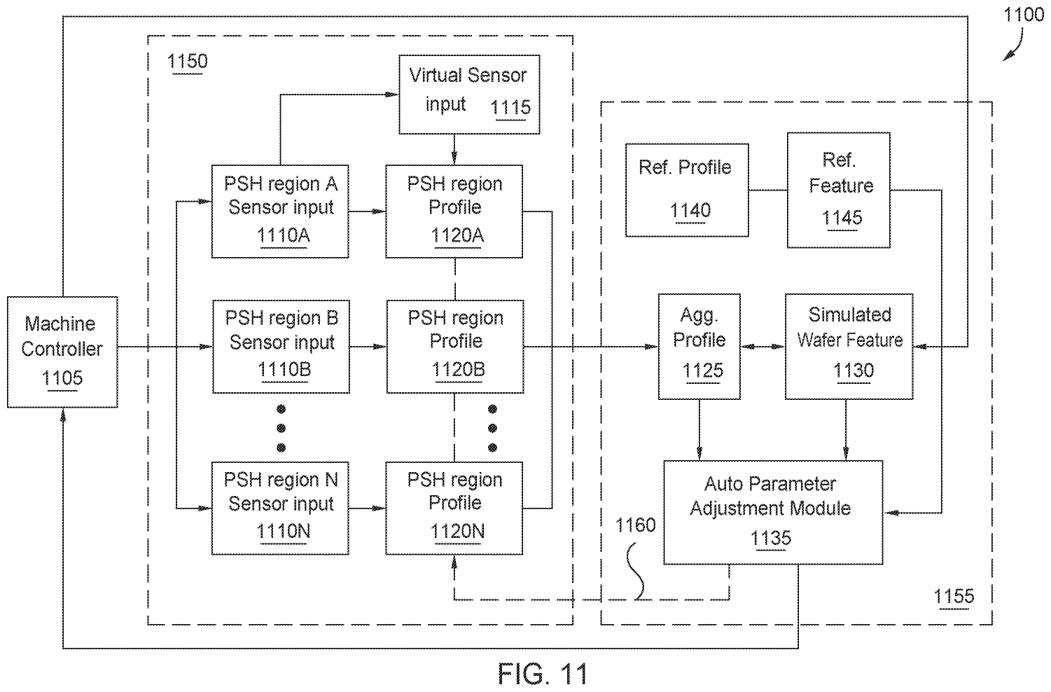

FIG. 11 depicts an exemplary environment within which embodiments of the present disclosure are practiced for real-time process control. Environment 1100 depicts a gas flow simulation 1150 and a showerhead controller operations 1155. While these specific flow operations are shown in the figure for illustrative purposes, other operations may also be present in other embodiments.

In environment 1100, a machine controller 1105 controls at least one aspect of at least one pixelated showerhead region. As discussed herein, a PSH region may be any one or more nozzles located on a faceplate of a showerhead. In the exemplary FIG. 11, there can be N number of PSH regions. Machine controller 1105 may be a controller for the showerhead specifically, or a global controller for manufacturing equipment.

Real-time sensor input for each PSH region is input into gas flow simulation 1150. That is, PSH region A sensor input 1110A, PSH region B sensor input 1110B, and PSH region N sensor input 1110N are all input into the gas flow simulation 1150. As discussed herein, there can be any number of PSH regions delineated on a faceplate of a showerhead, typically between 1-20 regions.

The gas flow simulation 1150 continues with virtual sensor input 1115 generated from the real-time sensor input of each PSH region. An output of the virtual sensors 1115 is used to generate a gas or plasma profile of each PSH region, such PSH region profile 1120A, PSH region profile 1120B, and PSH region profile 1120N.

The individual PSH region profiles are combined in a showerhead control process 1155 into one aggregate profile 1125 for the wafer as a whole. The aggregate profile 1125 is then used to simulate a particular wafer feature and generate a simulated wafer feature 1130.

An auto parameter adjustment module 1135 (which may be part of the matching network model 192 of FIG. 1) compares any differences between the aggregate profile 1125 and a target reference profile 1140, along with a comparison of any differences between a simulated wafer feature 1130 with a reference feature 1145. If there are differences between the simulated wafer feature and/or profile, compared to the reference wafer feature and/or profile, then the auto parameter adjustment module 1135 may determine an adjustment that can be made to one or more nozzles of the showerhead during the current physical process run to correct for the differences.

Before the process adjustments are implemented, they may be sent via path 1160 to the gas flow simulation 1150 to re-calculate a simulated profile for the individual PSH regions. From this, a new aggregate profile is generated along with a new simulated wafer feature. The new aggregate profile and simulated wafer feature are compared by the auto parameter adjustment module 1135 to the reference profile 1140 and reference wafer feature 1145. If the adjustment would improve the performance of the physical process by at least a certain threshold amount, then the parameter adjustment is sent to the machine controller 1105 to actually adjust the concurrent physical process run. If the parameter adjustment would not improve the performance of the physical process by at least a certain threshold amount, then the auto parameter adjustment module 1135 may determine a different feature adjustment to be made and send this further adjustment via path 1160 to the gas flow simulation of each showerhead region again.

In various embodiments, the auto parameter adjustment module 1135 continues the feedback loop in an iterative fashion until a satisfactory result is achieved in that the simulated aggregate profile and simulated wafer feature match the corresponding reference values within a predetermined threshold. While FIG. 11 is depicted in terms of PSH operations, a similar process can be utilized for individualized control of regions of an electrostatic chuck, and for individualized control of regions of a generated plasma.

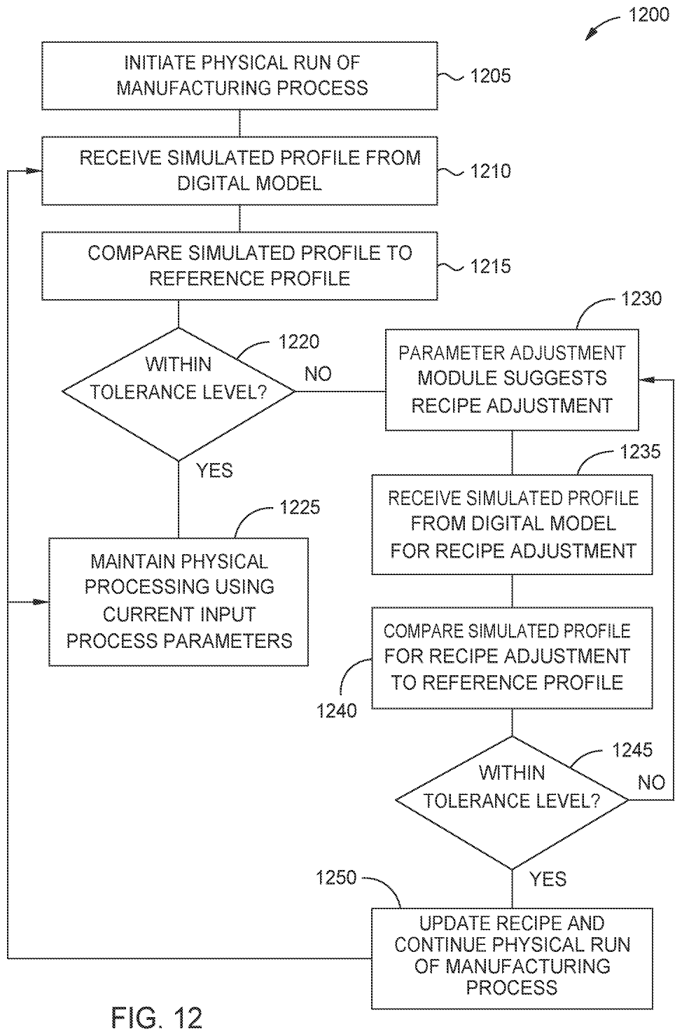

FIG. 12 depicts an exemplary method 1200 for real-time control of a manufacturing process with autonomous parameter adjustment. At block 1205, a controller initiates a physical run of a manufacturing process in a processing chamber, according to a recipe. As discussed herein, the manufacturing process may be a pixelated showerhead related manufacturing process, an electrostatic chuck related manufacturing process, or any other manufacturing process related to the generation of plasma in the processing chamber. While not depicted in the figure, the controller may also transmit process or recipe information to a digital simulation (which may be a digital twin model) that operates concurrently with the physical process. The digital simulation may run on a processor in the controller itself, or on a separate processor.

In one embodiment, at block 1205, a controller causes a manufacturing equipment to release at least one gaseous substance through a plurality of regions of a pixelated showerhead at a specified flow rate for a manufacturing process. In another embodiment, at block 1205, a controller causes a plurality of individually tunable heaters to heat a plurality of regions of an electrostatic chuck to a specified temperature for a manufacturing process. Each of the plurality of individually tunable heaters may be associated with at least one region of the electrostatic chuck.

In another embodiment, a controller causes a plurality of individually tunable RF field generators to generate a plasma across a plurality of regions in a processing chamber conducting a manufacturing process. Each of the individually tunable RF field generators may be associated with at least one region of the processing chamber. In a further embodiment, a controller causes a manufacturing equipment to do two or more of the above embodiments in combination.

At block 1210, the controller receives a simulated profile from the digital model operating concurrently with the physical manufacturing process. The digital model receives metrology data and/or sensor data from the processing chamber. Combined with a previously generated model of the chamber and the process parameters for the process currently in operation, the digital model simulates what a predicted processed semiconductor wafer will look like, if the current trajectory continues. Alternatively, the model may predict what a particular feature of the semiconductor wafer will look like at the termination of the process.

In one embodiment, the controller receives, at block 1210, from a trained digital simulation associated with the manufacturing equipment, a gas profile for each of the plurality of regions of the pixelated showerhead. In another embodiment, the controller receives, at block 1210, from a trained digital simulation associated with the electrostatic chuck, a heat profile for each of the plurality of regions of the ESC. In another embodiment, the controller receives, from a trained digital simulation associated with the processing chamber, a plasma profile for each of the plurality of regions of the processing chamber. In a further embodiment, the controller receives two of more of the gas profile, heat profile, or plasma profile from trained digital simulations.

At block 1215, the controller compares the simulated profile generated by the digital model to a target reference profile previously stored in memory (e.g., in data store 140 of FIG. 1). The target reference profile may be a target profile that the manufacturing process is attempting to achieve. At block 1220, the controller determines if the simulated predicted profile matches the target reference profile within a predetermined tolerance level. If so, the controller maintains the current process parameters at block 1225 and the manufacturing process continues. The controller returns to block 1210 with the receipt of a new simulated profile from the digital twin model. That is, the digital model continues to operate iteratively while the physical process occurs.

If the controller determines at block 1220 that the simulated predicted profile does not match the target reference profile within a predetermined tolerance level, then a parameter adjustment module suggests one or more corrective actions, such as a recipe adjustment, at block 1230, using one or more previously trained machine learning models. The suggested recipe adjustment is a prediction of a recipe change that can be implemented in the process chamber to attempt to bring the predicted simulated profile more in line with the target reference profile before wafer processing concludes.

In one embodiment, the one or more corrective actions is a change in a flow rate of at least one gaseous substance through at least one of the plurality of regions of the pixelated showerhead. In another embodiment, the one or more corrective actions is a change in a rate of heating applied by at least one of the individually tunable heaters to at least one region of the ESC. In another embodiment, the one or more corrective actions is a change in a rate of heating applied by at least one of the individually tunable RF field generators. In a further embodiment, the one or more corrective actions is a combination of two or more of these embodiments.

The suggested recipe adjustment is input into the digital model again to generate a new simulated profile for the adjusted recipe, which is received by the controller at block 1235. The simulated profile for the adjusted recipe is compared at block 1240 to the target reference profile again, and the controller determines if the simulated profile for the adjusted recipe is within a tolerance level of the target reference profile at block 1245. If the simulated profile for the adjusted recipe is within a predetermined tolerance level to the target reference profile, then the controller implements the adjusted recipe by adjusting one or more parameters of the process chamber at block 1250, and continues with the wafer processing. Then the controller returns to block 1210 to continue with the wafer processing and receive an updated simulated predicted profile.

If the controller determines at block 1245 that the simulated predicted profile for the adjusted recipe is not within a tolerance level of a target reference profile, then the method 1200 returns to block 1230 and the parameter adjustment module suggests a further recipe adjustment. In this way, real-time control of a manufacturing process is achieved with autonomous parameter adjustment. Further, any potential process drifts or deviations can be detected and compensated for in substantially real-time, reducing potential manufacture of defective products. In addition, the autonomous parameter adjustment allows for the manufacturing process to operate and correct itself without the need for human intervention.

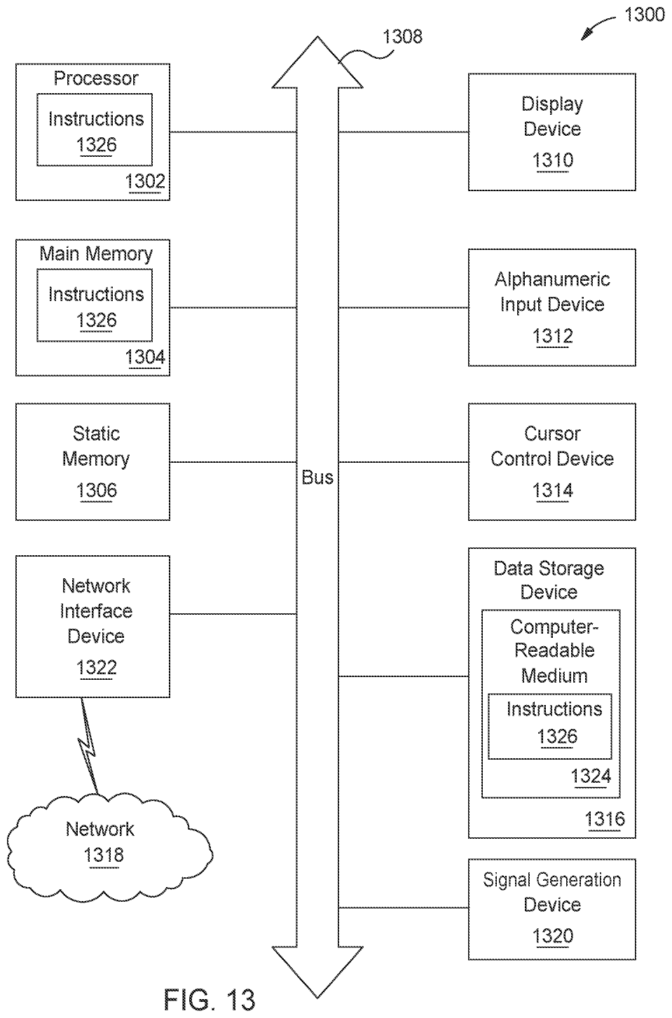

FIG. 13 illustrates an example machine of a computer system 1300 within which a set of instructions, for causing the machine to perform any one or more of the methodologies discussed herein, may be executed. In alternative implementations, the machine may be connected (e.g., networked) to other machines in a LAN, an intranet, an extranet, and/or the Internet. The machine may operate in the capacity of a server or a client machine in client-server network environment, as a peer machine in a peer-to-peer (or distributed) network environment, or as a server or a client machine in a cloud computing infrastructure or environment.

The machine may be a personal computer (PC), a tablet PC, a set-top box (STB), a web appliance, a server. a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 1300 includes a processing device 1302, a main memory 1304 (e.g., read-only memory (ROM), flash memory, dynamic random access memory (DRAM) such as synchronous DRAM (SDRAM) etc.), a static memory 1306 (e.g., flash memory, static random access memory (SRAM), etc.), and a data storage device 1316, which communicate with each other via a bus 1308.

Processing device 1302 represents one or more general-purpose processing devices such as a microprocessor, a central processing unit, or the like. More particularly, the processing device may be complex instruction set computing (CISC) microprocessor, reduced instruction set computing (RISC) microprocessor, very long instruction word (VLIV) microprocessor, or processor implementing other instruction sets, or processors implementing a combination of instruction sets. Processing device 1302 may also be one or more special-purpose processing devices such as an application specific integrated circuit (ASIC), a field programmable gate array (FPGA), a digital signal processor (DSP), network processor, or the like. The processing device 1302 is configured to execute instructions for performing the operations and steps discussed herein.

The computer system 1300 may further include a network interface device 1322 to communicate over a network 1318. The computer system 1300 also may include a video display device 1310 (e.g., a liquid crystal display (LCD) or a cathode ray tube (CRT)), an alphanumeric input device 1312 (e.g., a keyboard), a cursor control device 1314 (e.g., a mouse or a touch pad).). a signal generation device 1320 (e.g., a speaker), a graphics processing unit (not shown), video processing unit (not shown), and audio processing unit (not shown).

The data storage device 1316 may include a machine-readable storage medium 1324 (also known as a computer-readable medium) on which is stored one or more sets of instructions 1326 or software embodying any one or more of the methodologies or functions described herein. The instructions 1326 may also reside, completely or at least partially, within the main memory 1304 and/or within the processing device 1302 during execution thereof by the computer system 1300, the main memory 1304 and the processing device 1302 also constituting machine-readable storage media.

In one implementation, the instructions 1326 include instructions to implement functionality corresponding to a digital twin model. While the machine-readable storage medium 1324 is shown in an example implementation to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as “identifying” or “determining” or “executing” or “performing” or “collecting” or “creating” or “sending” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage devices.

The present disclosure also relates to an apparatus for performing the operations herein. This apparatus may be specially constructed for the intended purposes, or it may comprise a general purpose computer selectively activated or reconfigured by a computer program stored in the computer. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems may be used with programs in accordance with the teachings herein, or it may prove convenient to construct a more specialized apparatus to perform the method. The structure for a variety of these systems will appear as set forth in the description. In addition, the present disclosure is not described with reference to any particular programming language. It will be appreciated that a variety of programming languages may be used to implement the teachings of the disclosure as described herein.

The present disclosure may be provided as a computer program product, or software, that may include a machine-readable medium having stored thereon instructions, which may be used to program a computer system (or other electronic devices) to perform a process according to the present disclosure. A machine-readable medium includes any mechanism for storing information in a form readable by a machine (e.g., a computer). For example, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing specification, implementations of the disclosure have been described with reference to specific example implementations thereof. It will be evident that various modifications may be made thereto without departing from the broader spirit and scope of implementations of the disclosure as set forth in the following claims. The specification and drawings are, accordingly, to be regarded in an illustrative sense rather than a restrictive sense.

While the foregoing is directed to embodiments of the present disclosure, other and further embodiments of the disclosure may be devised without departing from the basic scope thereof. It is contemplated that elements and features of any one disclosed embodiment may be beneficially incorporated in one or more other embodiments. While the foregoing is directed to embodiments of the present disclosure, other and further embodiments of the disclosure may be devised without departing from the basic scope thereof, and the scope thereof is determined by the claims that follow.

1. A method comprising:
causing a manufacturing equipment to release at least one gaseous substance through a plurality of regions of a pixelated showerhead at a specified flow rate for a manufacturing process;
obtaining, from a trained digital simulation associated with the manufacturing equipment, a gas profile for each of the plurality of regions of the pixelated showerhead;
simulating a wafer feature based at least in part on the obtained gas profile, the simulation predicting at least one feature of a processed wafer to be generated by the manufacturing process; and
causing, based on the prediction, performance of one or more corrective actions associated with the manufacturing equipment.

2. The method of claim 1, further comprising: comparing the simulated wafer feature to a target reference wafer feature.

3. The method of claim 1, further comprising: determining that the simulated wafer feature deviates from a target reference wafer feature by at least a predetermined threshold amount, prior to causing performance of the one or more corrective actions.

4. The method of claim 1, wherein the one or more corrective actions associated with the manufacturing equipment comprises a change in a flow rate of the at least one gaseous substance through at least one of the plurality of regions of the pixelated showerhead.

5. The method of claim 1, further comprising:
receiving metrology information from at least one in situ, ex situ, or onboard metrology tool, prior to obtaining the gas profile information from the digital simulation.

6. The method of claim 1, further comprising:
obtaining from the digital simulation, an updated gas profile for each of the plurality of regions of the pixelated showerhead based on performance of the one or more corrective actions, prior to causing performance of the one or more corrective actions.

7. A method comprising:
causing a plurality of individually tunable heaters to heat a plurality of regions of an electrostatic chuck to a specified temperature for a manufacturing process, wherein at least one of the plurality of individually tunable heaters is associated with at least one region of the electrostatic chuck;
obtaining, from a trained digital simulation associated with the electrostatic chuck, a heat profile for each of the plurality of regions of the electrostatic chuck;
simulating a wafer feature based at least in part on the obtained heat profile, the simulation predicting at least one feature of a processed wafer to be generated by the manufacturing process; and
causing, based on the prediction, performance of one or more corrective actions associated with the manufacturing process.

8. The method of claim 7, further comprising: comparing the simulated wafer feature to a target reference wafer feature.

9. The method of claim 7, further comprising: determining that the simulated wafer feature deviates from a target reference wafer feature by at least a predetermined threshold amount, prior to causing performance of the one or more corrective actions.

10. The method of claim 7, wherein the one or more corrective actions associated with the manufacturing process comprises a change in a rate of heating applied by at least one of the individually tunable heaters to the at least one region of the electrostatic chuck.

11. The method of claim 7, further comprising:
receiving metrology information from at least one in situ, ex situ, or onboard metrology tool, prior to obtaining the heat profile information from the digital simulation.

12. The method of claim 7, further comprising:
obtaining from the digital simulation, an updated heat profile for each of the plurality of regions of the electrostatic chuck based on performance of the one or more corrective actions, prior to causing performance of the one or more corrective actions.

13. A method comprising:
causing a plurality of individually tunable RF field generators to generate a plasma across a plurality of regions in a processing chamber conducting a manufacturing process, wherein at least one of the plurality of individually tunable RF field generators is associated with at least one region of the processing chamber;
obtaining, from a trained digital simulation associated with the processing chamber, a plasma profile for each of the plurality of regions of the processing chamber;
simulating a wafer feature based at least in part on the obtained plasma profile, the simulation predicting at least one feature of a processed wafer to be generated by the manufacturing process; and
causing, based on the prediction, performance of one or more corrective actions associated with the manufacturing process.

14. The method of claim 13, further comprising: comparing the simulated wafer feature to a target reference wafer feature.

15. The method of claim 13, further comprising: determining that the simulated wafer feature deviates from a target reference wafer feature by at least a predetermined threshold amount, prior to causing performance of the one or more corrective actions.

16. The method of claim 13, wherein the one or more corrective actions associated with the manufacturing process comprises a change in a rate of heating applied by at least one of the individually tunable RF field generators.

17. The method of claim 13, further comprising:
receiving metrology information from at least one in situ, ex situ, or onboard metrology tool, prior to obtaining the plasma profile information from the digital simulation.

18. The method of claim 13, further comprising
obtaining from the digital simulation, an updated plasma profile for each of the plurality of regions of the processing chamber based on performance of the one or more corrective actions, prior to causing performance of the one or more corrective actions.

19. A method comprising:
causing a plurality of individually tunable heaters to heat a plurality of regions of an electrostatic chuck to a specified temperature for a manufacturing process, wherein at least one of the plurality of individually tunable heaters is associated with at least one region of the electrostatic chuck;
causing a plurality of individually tunable RF field generators to generate a plasma across a plurality of regions in a processing chamber conducting the manufacturing process, wherein at least one of the plurality of individually tunable RF field generators is associated with at least one region of the processing chamber;
obtaining, from a trained digital simulation associated with the electrostatic chuck, heat profile information for each of the plurality of regions of the electrostatic chuck;
obtaining, from a trained digital simulation associated with the processing chamber, plasma profile information for each of the plurality of regions of the processing chamber;
simulating a wafer feature based in part on at least one of the heat profile information or the plasma profile information, the simulation predicting at least one feature of a processed wafer to be generated by the manufacturing process; and
causing, based on the prediction, performance of one or more corrective actions associated with the manufacturing process.

20. The method of claim 19, further comprising:
obtaining from the digital simulation, at least one of updated heat profile information or at least one of updated plasma profile information for each of the plurality of respective regions based on performance of the one or more corrective actions, prior to causing performance of the one or more corrective actions.
